(19) United States
(12) Patent Application Publication
(10) Pub. No.: US 2024/0340554 A1
(43) Pub. Date: Oct. 10, 2024

(54) IMAGING DEVICE

(71) Applicant: Sony Semiconductor Solutions Corporation, Kanagawa (JP)

(72) Inventors: Kyosuke Ito, Kanagawa (JP); Toshihisa Makihira, Fukuoka (JP)

(21) Appl. No.: 18/293,605

(22) PCT Filed: Jul. 21, 2022
(86) PCT No.: PCT/JP22/28402

§ 371 Date: Jan. 30, 2024

(30) Foreign Application Priority Data
Aug. 24, 2021 (JP) 2021-136135

(51) Int. Cl. H04N 25/778; H04N 25/13; H04N 25/627; H04N 25/704

(52) U.S. Cl. CPC H04N 25/778; H04N 25/627; H04N 25/704; H04N 25/134

(57) ABSTRACT

[Problem] To provide an imaging device capable of increasing pixel density and changing an imaging magnification.

[Solution] An imaging device includes: a photoelectric converter; a pixel region having a plurality of combinations of transfer transistors having one set of ends connected to the photoelectric converter; a first floating diffusion connected to the other set of ends of the plurality of transfer transistors; a separation transistor having one end connected to the first floating diffusion; a second floating diffusion connected to the other end of the separation transistor; and a reset transistor having one end connected to the other end of the separation transistor and the other end supplied with a predetermined potential. The separation transistor is put into a disconnected state and the reset transistor is put into a connected state.

### TECHNICAL FIELD

The present disclosure relates to an imaging device that images a subject.

### BACKGROUND ART

In imaging devices, the density of pixels is increasing, and techniques for suppressing charges leakage are being developed. Furthermore, there are devices that obtain an image plane phase difference in order to realize autofocus.

### CITATION LIST

### Patent Literature

### [PTL 1]

JP 2018-93992A

### SUMMARY

### Technical Problem

There is a demand for an imaging device that can increase the density of pixels and change an imaging magnification. Therefore, the present disclosure provides an imaging device that can increase the density of pixels and change an imaging magnification.

### Solution to Problem

In order to solve the problem, according to the present disclosure, there is provided an imaging device including:
a plurality of pixel blocks each having a plurality of light-receiving pixels including color filters of the same color, and the plurality of light-receiving pixels being divided into a plurality of pixel pairs each including two light-receiving pixels; and
a plurality of lenses each provided at a position corresponding to the plurality of pixel pairs, wherein
the pixel block includes:
a photoelectric converter,
a first floating diffusion having a plurality of combinations of transfer transistors having one set of ends connected to the photoelectric converter and being connected to the other set of ends of the plurality of transfer transistors;
a separation transistor having one end connected to the first floating diffusion;
a second floating diffusion connected to the other end of the separation transistor; and
a reset transistor having one end connected to the other end of the separation transistor, and the other end being supplied with a predetermined potential.

The separation transistor may be put into a disconnected state and the reset transistor may be put into a connected state.

At least one of the plurality of transfer transistors may be put into a connected state according to the connected state of the reset transistor.

When the reset transistor may be in a connected state, a potential of the first floating diffusion may go higher due to a first stray capacitance between a gate of the reset transistor and the first floating diffusion.

After the separation transistor and the reset transistor are put into a connected state, the separation transistor may be put into a disconnected state, and at least one of the transfer transistors may be put into a connected state according to the disconnected state of the separation transistor.

After the separation transistor and the reset transistor are put into a connected state, the separation transistor may be put into a disconnected state, the reset transistor may be put into a disconnected state, and at least one of the transfer transistors may be put into a connected state according to reconnection of the reset transistor.

After the separation transistor and the reset transistor are put into a connected state, the separation transistor may be put into a disconnected state, and at least one of the transfer transistors may be put into a connected state according to disconnection of the separation transistor.

A second stray capacitance between the gate of the transfer transistor and the other end of the transfer transistor may increase the potential of the first floating diffusion when the transfer transistor is put into a connected state.

When transferring charges stored in the photoelectric converter connected to the one end of the transfer transistor to the first floating diffusion, the other transfer transistors to which charges have already been transferred may be put into a connected state.

The second stray capacitance corresponding to the other transfer transistor to which charges have already been transferred may be configured to be larger than the second stray capacitance corresponding to the transfer transistor to which charges are to be transferred next.

The image data may further include:
an amplification transistor having a gate connected to the first floating diffusion;
a selection transistor having one end connected to the amplification transistor and the other end connected to a signal line; and
a voltage control circuit that controls a voltage of the signal line when the transfer transistor is put into a connected state.

When the plurality of transfer transistors are put into a connected state, the periods in which the plurality of transfer transistors are in a connected state may not overlap.

When transferring charges stored in the photoelectric converter connected to the one end of the transfer transistor to the first floating diffusion, the other transfer transistor to which charges have already been transferred may be put into a connected state.

When transferring charges stored in the plurality of photoelectric converters to at least the first floating diffusion, periods of the connection state of the plurality of the transfer transistors may not overlap.

The imaging device may further include:
an amplification transistor having a gate connected to the first floating diffusion;
a selection transistor having one end connected to the amplification transistor and the other end connected to a signal line; and
a voltage control circuit that controls a voltage of the signal line when the transfer transistor is put into a connected state.

The two light-receiving pixels may be arranged in parallel in a first direction, and in each of the plurality of pixel blocks, the two pixel pairs arranged in a second direction intersecting the first direction may be arranged to be shifted in the first direction.

The plurality of pixel blocks may include a first pixel block and a second pixel block,
in the first pixel block, the plurality of light-receiving pixels may be arranged in a first arrangement pattern,
in the second pixel block, the plurality of light-receiving pixels may be arranged in a second arrangement pattern.

The number of the plurality of light-receiving pixels in the first pixel block may be greater than the number of the plurality of light-receiving pixels in the second pixel block, and
the plurality of light-receiving pixels included in the first pixel block may include the green color filter.

### BRIEF DESCRIPTION OF DRAWINGS

FIG. 1 is a diagram showing an example of the configuration of an imaging device according to a first embodiment.

FIG. 2 is a diagram showing an example of the arrangement of light-receiving pixels in a pixel array.

FIG. 3 is a diagram showing an example of a schematic cross-sectional structure of a pixel array.

FIG. 4 is a diagram showing an example of the configuration of a pixel block.

FIG. 5 is a diagram showing an example of the configuration of another pixel block.

FIG. 6 is a diagram showing a wiring example of a pixel block.

FIG. 7A is a diagram showing an example of the configuration of a reader.

FIG. 7B is a diagram showing an example of an image signal.

FIG. 8 is a diagram showing an example of arrangement of pixels in a pixel block.

FIG. 9 is a diagram showing an example of a timing chart for readout driving of ten pixels in a pixel block.

FIG. 10 is a diagram schematically showing the potential of pixel 1 when the control signal goes high.

FIG. 11 is a diagram schematically showing the potential of pixel 2 when the control signal goes high.

FIG. 12 is a diagram schematically showing the potential when only one control signal goes high in pixel 2.

FIG. 13 is a diagram showing an example of a timing chart of detailed readout driving of ten pixels in a pixel block.

FIG. 14 is a diagram showing an example of the configuration of a part of a pixel block according to the second embodiment.

FIG. 15 is a diagram showing an example of a timing chart for readout driving of ten pixels in the pixel block (FIG. 4).

FIG. 16 is a diagram illustrating an operation example when driving a voltage control circuit as a sunspot correction circuit.

FIG. 17A is a solar image in which the voltage control circuit is driven as a sunspot correction circuit.

FIG. 17B is a solar image when the voltage control circuit is not driven as a sunspot correction circuit.

FIG. 18 is a diagram showing an example of the configuration of a part of a pixel block according to a second embodiment.

FIG. 19 is a diagram schematically showing the potential of a pixel.

FIG. 20 is a timing chart showing an example of driving for reading charges from pixels.

FIG. 21 is a diagram schematically showing the state of movement of electrons under the gate of a transistor.

FIG. 22 is a timing chart showing another example of driving for reading charges from pixels.

FIG. 23 is a diagram showing an example of the configuration of a pixel block for explaining the feed-through.

FIG. 24 is a timing chart of an example of readout driving of the pixel block in FIG. 23.

FIG. 25 is a diagram showing a further example of the configuration of a part of the pixel block shown in FIG. 24.

FIG. 26 is a diagram schematically showing an example of arrangement of pixels and on-chip lenses.

FIG. 27 is a diagram showing an output signal when a first floating diffusion is used and an output signal when the first and second floating diffusions are used.

FIG. 28 is a diagram showing an example of the number of light-receiving pixels (the number of effective pixels) when the zoom magnification is changed.

FIG. 29 is a diagram showing an example of a zoom operation in an imaging device.

FIG. 30 is a diagram illustrating an example of the operation of the imaging device in an imaging mode.

FIG. 31 is a diagram illustrating an example of a readout operation when generating an image plane phase difference.

FIG. 32 is a diagram illustrating an example of image processing by a signal processor in the imaging mode.

FIG. 33 is a diagram showing an example of a readout operation in the case of low resolution readout.

### DESCRIPTION OF EMBODIMENTS

Hereinafter, embodiments of an imaging device will be described with reference to the drawings. Hereinafter, main components of the imaging device will be mainly described, but the imaging device may have components or functions that are not illustrated or described. The following description does not exclude components or functions that are not illustrated or described.

### First Embodiment

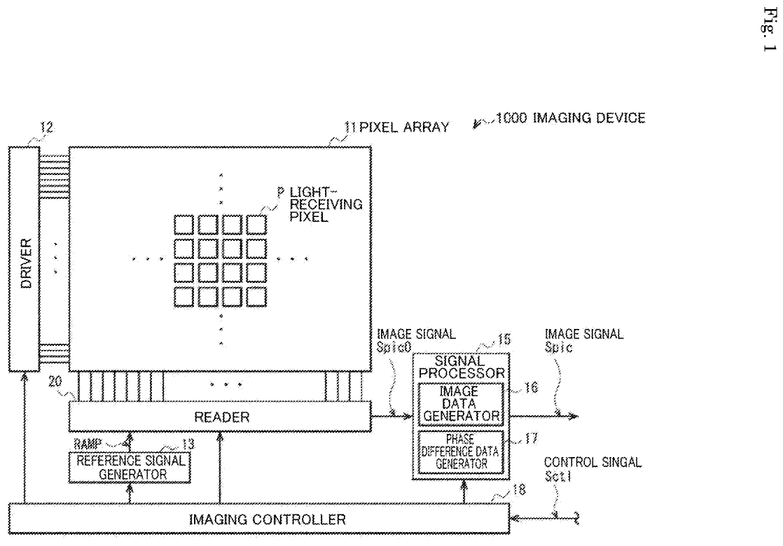

FIG. 1 is a diagram illustrating an example of the configuration of an imaging device 1000 according to the first embodiment. The imaging device 1000 includes a pixel array 11, a driver 12, a reference signal generator 13, a reader 20, a signal processor 15, and an imaging controller 18.

The pixel array 11 has a plurality of light-receiving pixels P arranged in a matrix. The light-receiving pixel P is configured to generate a signal SIG including a pixel voltage Vpix corresponding to the amount of light received.

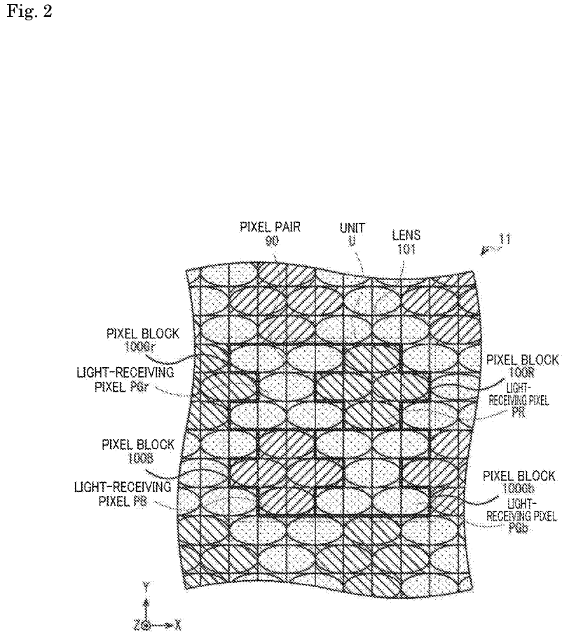

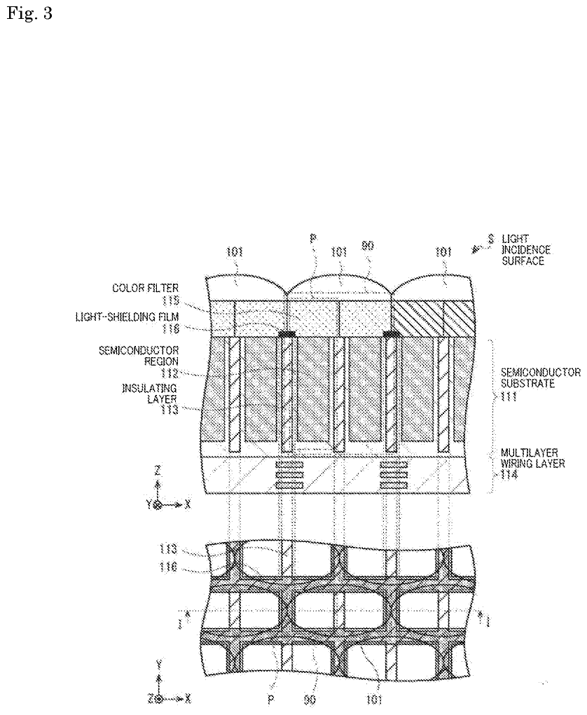

FIG. 2 is a diagram showing an example of the arrangement of light-receiving pixels P in the pixel array 11. FIG. 3 is a diagram showing an example of a schematic cross-sectional structure of the pixel array 11. The pixel array 11 includes a plurality of pixel blocks 100 and a plurality of lenses 101.

The plurality of pixel blocks 100 include pixel blocks 100R, 100Gr, 100Gb, and 100B. In the pixel array 11, the plurality of light-receiving pixels P are arranged with four pixel blocks 100 (pixel blocks 100R, 100Gr, 100Gb, and 100B) as a unit (unit U).

The pixel block 100R has eight light-receiving pixels P (light-receiving pixels PR) including a red (R) color filter 115, the pixel block 100Gr has ten light-receiving pixels P (light-receiving pixels PGr) including a green (H) color filter 115, the pixel block 100Gb has ten light-receiving pixels P (light-receiving pixels PGb) including a green (H) color filter 115, and the pixel block 100B has eight light-receiving pixels P (light-receiving pixels PB) including a blue (C) color filter 115. In FIG. 2, the difference in color of the color filter is expressed using shading. The arrangement pattern of the light-receiving pixels PR in the pixel block 100R and the arrangement pattern of the light-receiving pixels PB in the pixel block 100B are the same, and the arrangement pattern of the light-receiving pixels PGr in the pixel block 100Gr and the arrangement pattern of the light-receiving pixels PGb in the pixel block 100Gb are the same. In the unit U, the pixel block 100Gr is arranged at the upper left, the pixel block 100R is arranged at the upper right, the pixel block 100B is arranged at the lower left, and the pixel block 100Gb is arranged at the lower right. In this way, the pixel blocks 100R, 100Gr, 100Gb, and 100B are arranged in a so-called Bayer arrangement, with each pixel block 100 as a unit.

As shown in FIG. 3, the pixel array 11 includes a semiconductor substrate 111, a semiconductor region 112, an insulating layer 113, a multilayer wiring layer 114, a color filter 115, and a light-shielding film 116. The semiconductor substrate 111 is a support substrate on which the imaging device 1000 is formed, and is a P-type semiconductor substrate. The semiconductor region 112 is a semiconductor region provided in the substrate of the semiconductor substrate 111 at a position corresponding to each of the plurality of light-receiving pixels P, and is doped with an N-type impurity to form a photodiode PD. The insulating layer 113 is provided at the boundary of a plurality of light-receiving pixels P arranged in parallel in the XY plane in the substrate of the semiconductor substrate 111, and in this example, is a DTI (Deep Trench Isolation) configured using an oxide film or the like. The multilayer wiring layer 114 is provided on the semiconductor substrate 111 on the surface opposite to the light incidence surface S of the pixel array 11, and includes a plurality of wiring layers and an interlayer insulating film. The wiring in the multilayer wiring layer 114 is configured to connect, for example, a transistor (not shown) provided on the surface of the semiconductor substrate 111 to the driver 12 and the reader 20. The color filter 115 is provided on the semiconductor substrate 111 on the light incidence surface S of the pixel array 11. The light-shielding film 116 is provided on the light incidence surface S of the pixel array 11 so as to surround two light-receiving pixels P (hereinafter also referred to as a pixel pair 90) arranged in parallel in the X direction. Note that the photodiode PD according to the present embodiment corresponds to a photoelectric converter.

The plurality of lenses 101 are so-called on-chip lenses, and are provided on the color filter 115 on the light incidence surface S of the pixel array 11. The lens 101 is provided above two light-receiving pixels P (pixel pair 90) arranged in parallel in the X direction. Four lenses 101 are provided above the eight light-receiving pixels P of the pixel block 100R, five lenses 101 are provided above the ten light-receiving pixels P of the pixel block 100Gr, five lenses 101 are provided above the ten light-receiving pixels P of the pixel block 100Gb, and four lenses 101 are provided above the eight light-receiving pixels P of the pixel block 100B. The lenses 101 are arranged in parallel in the X direction and the Y direction. The lenses 101 arranged in the Y direction are arranged to be shifted by one light-receiving pixel P in the X direction. In other words, the pixel pairs 90 arranged in the Y direction are arranged to be shifted by one light-receiving pixel P in the X direction.

With this configuration, in two light-receiving pixels P in the pixel pair 90 corresponding to one lens 101, images are shifted from each other. The imaging device 1000 generates phase difference data DF based on a so-called image plane phase difference detected by the plurality of pixel pairs 90. For example, in a camera equipped with the imaging device 1000, the amount of defocus is determined based on this phase difference data DF, and the position of the photographing lens is moved based on the amount of defocus. In this way the camera can achieve autofocus.

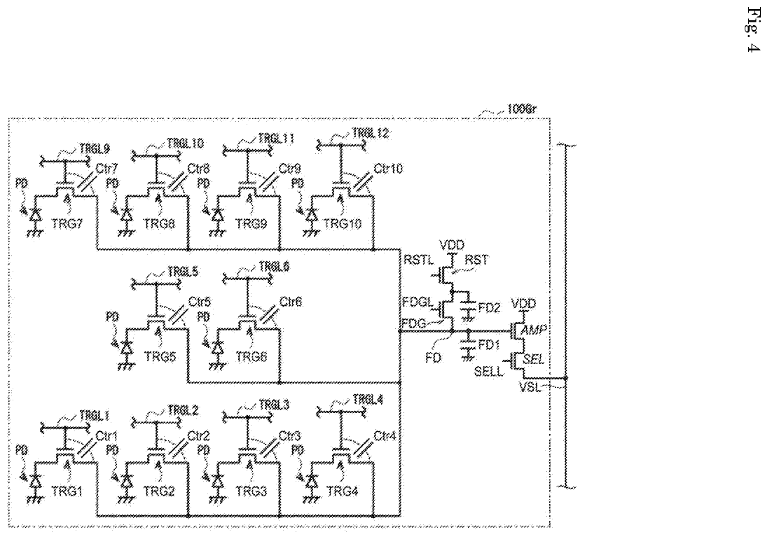

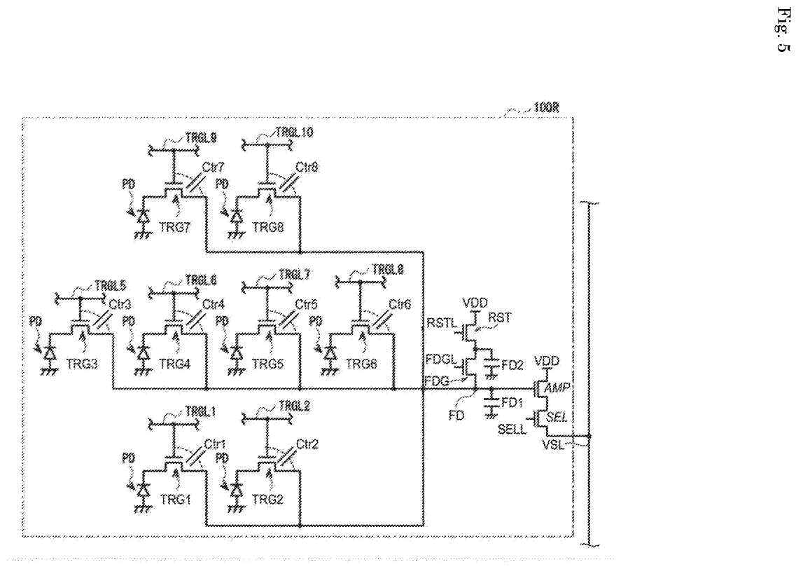

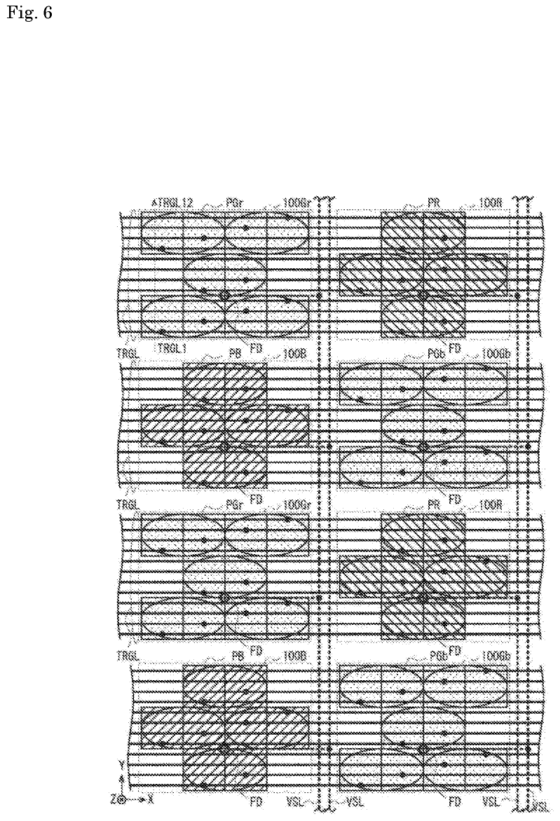

FIG. 4 is a diagram showing an example of the configuration of the pixel block 100Gr. FIG. 5 is a diagram showing an example of the configuration of the pixel block 100R. FIG. 6 is a diagram showing a wiring example of the pixel blocks 100R, 100Gr, 100Gb, and 100B. Note that, in FIG. 6, for convenience of explanation, the plurality of pixel blocks 100 are drawn separated from each other.

The pixel array 11 includes a plurality of control lines TRGL, a plurality of control lines RSTL, a plurality of control lines SELL, and a plurality of signal lines VSL. The control line TRGL extends in the X direction (horizontal direction in FIGS. 4 to 6), and one end is connected to the driver 12. A control signal STRG is supplied to the control line TRGL by the driver 12. The control line RSTL extends in the X direction, and one end is connected to the driver 12. A control signal SRST is supplied to this control line RSTL by the driver 12. The control line SELL extends in the X direction, and one end is connected to the driver 12. A control signal SSEL is supplied to this control line SELL by the driver 12. The signal line VSL extends in the Y direction (vertical direction in FIGS. 4 to 6), and one end is connected to the reader 20. This signal line VSL transmits the signal SIG generated by the light-receiving pixel P to the reader 20.

The pixel block 100Gr (FIG. 4) includes ten photodiodes PD, ten transistors TRG1 to TRG10, a first floating diffusion FD1, a second floating diffusion FD2, and transistors RST, FDG, AMP, and SEL. The pixel block 100Gr (FIG. 4) further has stray capacitances Ctr1 to Ctr10 parasitic to the node FD. Hereinafter, the capacitance connected to the node FD may be referred to as a floating diffusion FD. That is, the floating diffusion FD may include only the first floating diffusion FD1, or the first floating diffusion FD1 and the second floating diffusion FD2 may be connected in parallel. Note that the transistors TRG1 to TRG10 according to the present embodiment may be referred to as transfer transistors. In the present embodiment, the transistor RST may be referred to as a reset transistor, the transistor FDG may be referred to as a separation transistor, the transistor AMP may be referred to as an amplification transistor, and the transistor SEL may be referred to as a selection transistor.

The ten photodiodes PD and the ten transistors TRG1 to TRG10 respectively correspond to the ten light-receiving pixels PGr included in the pixel block 100Gr. The transistors TRG, FDG, RST, AMP, and SEL are N-type MOS (Metal Oxide Semiconductor) transistors in this example. Stray capacitances Ctr1 to Ctr10 are stray capacitances between the gates and drains of TRG1 to TRG10. The ten light-receiving pixels PGr are becoming increasingly finer, and each wiring is becoming more complex. Therefore, although the capacitances of the stray capacitances Ctr1 to Ctr10 may be different, they are configured so that (stray capacitance Ctr1)>(stray capacitance Ctr2 to Ctr10).

The photodiode PD is a photoelectric conversion element that generates an amount of charges corresponding to the amount of received light and stores the generated charges therein. The anode of the photodiode PD is grounded, and the cathode is connected to the sources of the transistors TRG1 to TRG10.

The gates of the ten transistors TRG1 to TRG10 are connected to different control lines TRGL among the ten control lines TRGL (in this example, control lines TRGL1 to TRGL6 and TRGL9 to TRGL12). The sources are connected to the cathode of the photodiode PD, and the drains are connected to the node FD.

The first floating diffusion FD1 is configured to store the charges transferred from the photodiode PD via the transistors TRG1 to TRG10. The first floating diffusion FD1 is configured using, for example, a diffusion layer formed on the surface of a semiconductor substrate. In FIG. 4, the first floating diffusion FD1 is shown using a symbol of a capacitive element.

This first floating diffusion FD1 is connected to the gate of the amplification transistor AMP, and is also connected to the second floating diffusion FD2 via the separation transistor FDG. In FIG. 4, the second floating diffusion FD2 is shown using a symbol of a capacitive element. That is, the drain of the separation transistor FDG is connected to the second floating diffusion FD2 and the source of the reset transistor RST. The gate of the separation transistor FDG is connected to the control line FRDGL, and the source is connected to the first floating diffusion FD1. For example, the capacitance of the second floating diffusion FD2 may be configured to be approximately 20 times the capacitance of the first floating diffusion FD1. The second floating diffusion FD2 may be formed of, for example, polysilicon. Alternatively the second floating diffusion FD2 may be formed using a diffusion layer formed on the surface of a semiconductor substrate.

The gate of the reset transistor RST is connected to the control line RSTL, the drain is connected to the power supply voltage VDD, and the source is connected to the second floating diffusion FD2 and the drain of the separation transistor FDG. The drain of the amplification transistor AMP is supplied with the power supply voltage VDD, and the source is connected to the drain of the selection transistor SEL. The gate of the selection transistor SEL is connected to the control line SELL, the drain is connected to the source of the amplification transistor AMP, and the source is connected to the vertical signal line VSL.

With this configuration, the first floating diffusion FD1 and the second floating diffusion FD2 connected to the node FD are reset by turning on the transistors FDG and RST based on the control signals SFDG and SRST. Furthermore, in the light-receiving pixel P, for example, when the transistors TRG, FDG, and RST are turned on based on the control signals STRG, SFDG, and SRST, the charges stored in the photodiode PD are discharged. Then, when these transistors TRG and RST are turned off, an exposure period T starts, and an amount of charges corresponding to the amount of light received is stored in the photodiode PD. At this time, when the transistor FDG is in the on state, the capacitance at the node FD is the capacitance of the first floating diffusion FD1 and the second floating diffusion FD2. On the other hand, when the transistor FDG is in the off state, the capacitance at the node FD is only the capacitance of the first floating diffusion FD1.

After the exposure period T ends, the light-receiving pixel P outputs a signal SIG including the reset voltage Vreset and the pixel voltage Vpix to the signal line VSL. More specifically, first, when the transistor SEL is turned on based on the control signal SSEL, the light-receiving pixel P is electrically connected to the signal line VSL. In this way, the transistor AMP is connected to a constant current source 21 (described later) of the reader 20, and operates as a so-called source follower. As described later, during the P phase (Pre-charge phase) period TP after the voltage of the node FD is reset by turning on the transistor RST, the light-receiving pixel P outputs a voltage corresponding to the voltage of the node FD at that time as a reset voltage Vreset. Note that in the present embodiment, the on state may be referred to as a connected state, and the off state may be referred to as a disconnected state.

In addition, during the D phase (Data phase) period TD after charges are transferred from the photodiode PD to the node FD by turning on the transistor TRG, the light-receiving pixel P outputs a voltage corresponding to the voltage of the node FD at that time as the pixel voltage Vpix. The voltage difference between the pixel voltage Vpix and the reset voltage Vreset corresponds to the amount of light received by the light-receiving pixel P during the exposure period T. In this way, the light-receiving pixel P outputs the signal SIG including the reset voltage Vreset and the pixel voltage Vpix to the signal line VSL.

The pixel block 100R (FIG. 5) includes eight photodiodes PD, eight transistors TRG1 to TRG8, a first floating diffusion FD1, a second floating diffusion FD2, and transistors RST, FDG, AMP, and SEL. The pixel block 100R (FIG. 5) further has stray capacitances Ctr1 to Ctr8 as parasitic stray capacitances of the node FD.

The eight photodiodes PD and the eight transistors TRG1 to TRG8 respectively correspond to the eight light-receiving pixels PR included in the pixel block 100R. The gates of the eight transistors TRG1 to TRG8 are connected to different control lines TRGL among the eight control lines TRGL (in this example, control lines TRGL1, TRGL2, and TRGL5 to TRGL10).

As shown in FIG. 6, pixel blocks 100Gr and 100R belonging to the same row and arranged in the X direction are connected to a plurality of control lines TRGL among the same twelve control lines TRGL (control lines TRGL1 to TRGL12). In this example, the control lines TRGL1 to TRGL12 are arranged in this order from the bottom to the top in FIG. 6. The pixel block 100Gr is connected to ten control lines TRGL (control lines TRGL1 to TRGL6 and TRGL9 to TRGL12) among the twelve control lines TRGL (control lines TRGL1 to TRGL12), and the pixel block 100R is connected to eight control lines TRGL (control lines TRGL1, TRGL2, and TRGL5 to TRGL10) among these twelve control lines TRGL (control lines TRGL1 to TRGL12).

Although not shown, pixel blocks 100Gr and 100R belonging to the same row and arranged in the X direction are connected to one control line RSTL, one control line FDGL, and one control line SELL.

Further, as shown in FIG. 6, pixel blocks 100Gr belonging to the same column and arranged in the Y direction are connected to one signal line VSL. Similarly pixel blocks 100R belonging to the same column and arranged in the Y direction are connected to one signal line VSL.

Like the pixel block 100R (FIG. 5), the pixel block 100B includes eight photodiodes PD, eight transistors TRG1 to TRG8, a first floating diffusion FD1, a second floating diffusion FD2, a transistor RST, FDG, AMP, and SEL. The pixel block 100R (FIG. 5) further has stray capacitances Ctr1 to Ctr8 as parasitic stray capacitances of the node FD. The eight photodiodes PD and the eight transistors TRG1 to TRG8 respectively correspond to the eight light-receiving pixels PB included in the pixel block 100B. The gates of the eight transistors TRG1 to TRG8 are connected to different control lines TRGL among the eight control lines TRGL.

Like the pixel block 100Gr (FIG. 4), the pixel block 100Gb includes ten photodiodes PD, ten transistors TRG1 to TRG10, a first floating diffusion FD1, a second floating diffusion FD2, and transistors RST, FDG, AMP, and SEL. The pixel block 100Gb further has stray capacitances Ctr1 to Ctr10 as parasitic stray capacitances of the node FD. The ten photodiodes PD and the ten transistors TRG1 to TRG10 respectively correspond to the ten light-receiving pixels PGb included in the pixel block 100Gb. The gates of the ten transistors TRG are connected to different control lines TRGL among the ten control lines TRGL.

As shown in FIG. 6, pixel blocks 100B and 100Gb belonging to the same row and arranged in the X direction are connected to a plurality of control lines TRGL among the same twelve control lines TRGL. Although not shown, pixel blocks 100B and 100Gb belonging to the same row and arranged in the X direction are connected to one control line RSTL and one control line SELL. Further, as shown in FIG. 6, pixel blocks 100B belonging to the same column and arranged in the Y direction are connected to one signal line VSL. Similarly pixel blocks 100Gb belonging to the same column and arranged in the Y direction are connected to one signal line VSL.

The driver 12 (FIG. 1) is configured to drive the plurality of light-receiving pixels P in the pixel array 11 based on instructions from the imaging controller 18. Specifically the driver 12 the plurality of light-receiving pixels P in the pixel array 11 by supplying the plurality of control signals STRG to the plurality of control lines TRGL in the pixel array 11, supplying the plurality of control signals SRST to the plurality of control lines RSTL, and supplying the plurality of control signals SELL to the plurality of control lines SSEL.

The reference signal generator 13 is configured to generate a reference signal RAMP based on instructions from the imaging controller 18. The reference signal RAMP has a so-called ramp waveform in which the voltage level gradually changes over time during the period in which the reader 20 performs AD conversion (P-phase period TP and D-phase period TD). The reference signal generator 13 supplies such a reference signal RAMP to the reader 20.

The reader 20 is configured to generate the image signal Spic0 by performing AD conversion based on the signal SIG supplied from the pixel array 11 via the signal line VSL based on an instruction from the imaging controller 18.

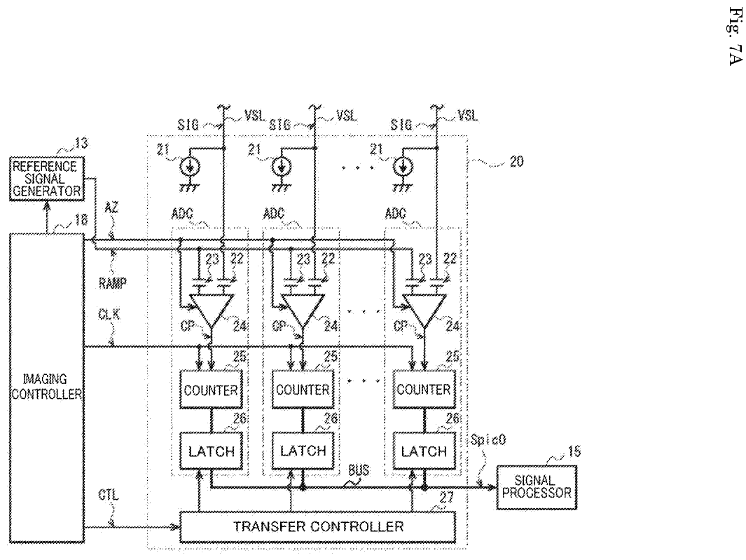

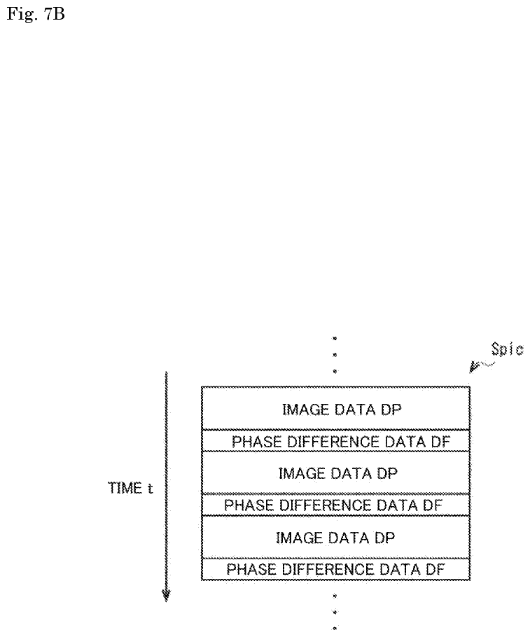

FIG. 7A is a diagram illustrating an example of the configuration of the reader 20. Note that in addition to the reader 20, FIG. 7A also depicts the reference signal generator 13, the signal processor 15, and the imaging controller 18. The reader 20 includes a plurality of constant current sources 21, a plurality of AD (Analog to Digital) converters ADC, and a transfer controller 27. A plurality of constant current sources 21 and a plurality of AD converters ADC are respectively provided corresponding to the plurality of signal lines VSL. The constant current source 21 and the AD converter ADC corresponding to one signal line VSL will be explained below.

The constant current source 21 is configured to cause a predetermined current to flow through the corresponding signal line VSL. One end of the constant current source 21 is connected to the corresponding signal line VSL, and the other end is grounded.

The AD converter ADC is configured to perform AD conversion based on the signal SIG on the corresponding signal line VSL. The AD converter ADC includes capacitive elements 22 and 23, a comparator circuit 24, a counter 25, and a latch 26.

One end of the capacitive element 22 is connected to the signal line VSL and supplied with the signal SIG, and the other end is connected to the comparator circuit 24. One end of the capacitive element 23 is supplied with the reference signal RAMP supplied from the reference signal generator 13, and the other end is connected to the comparator circuit 24.

The comparator circuit 24 is configured to generate the signal CP by performing a comparison operation based on the signal SIG supplied from the light-receiving pixel P via the signal line VSL and the capacitive element 22 and the reference signal RAMP supplied from the reference signal generator 13 via the capacitive element 23. The comparator circuit 24 sets the operating point by setting the voltages of the capacitive elements 22 and 23 based on the control signal AZ supplied from the imaging controller 18. After that, the comparator circuit 24 compares the reset voltage Vreset included in the signal SIG and the voltage of the reference signal RAMP during the P-phase period TP. In the D-phase period TD, a comparison operation is performed to compare the pixel voltage Vpix included in the signal SIG and the voltage of the reference signal RAMP.

The counter 25 is configured to perform a counting operation of counting the pulses of the clock signal CLK supplied from the imaging controller 18 based on the signal CP supplied from the comparator circuit 24. Specifically, the counter 25 generates a count value CNTP by counting the pulses of the clock signal CLK during the P-phase period TP until the signal CP transitions, and outputs this count value CNTP as a digital code having a plurality of bits. The counter 25 generates a count value CNTD by counting the pulses of the clock signal CLK during the D-phase period TD until the signal CP transitions, and outputs the count value CNTD as a digital code having a plurality of bits.

The latch 26 is configured to temporarily hold the digital code supplied from the counter 25 and output the digital code to the bus wiring BUS based on an instruction from the transfer controller 27.

The transfer controller 27 is configured to control the latches 26 of the plurality of AD converters ADC to sequentially output digital codes to the bus wiring BUS based on the control signal CTL supplied from the imaging controller 18. The reader 20 uses the bus wiring BUS to sequentially transfer a plurality of digital codes supplied from a plurality of AD converters ADC to the signal processor 15 as an image signal Spic0.

The signal processor 15 (FIG. 1) is configured to generate an image signal Spic by performing predetermined signal processing based on the image signal Spic0 and instructions from the imaging controller 18. The signal processor 15 includes an image data generator 16 and a phase difference data generator 17. The image data generator 16 is configured to generate image data DP representing a captured image by performing predetermined image processing based on the image signal Spic0. The phase difference data generator 17 is configured to generate phase difference data DF indicating the image plane phase difference by performing predetermined image processing based on the image signal Spic0. The signal processor 15 generates an image signal Spic including the image data DP generated by the image data generator 16 and the phase difference data DF generated by the phase difference data generator 17.

FIG. 7B is a diagram illustrating an example of the image signal Spic. The signal processor 15 generates the image signal Spic, for example, by alternately arranging image data DP related to multiple rows of light-receiving pixels P and phase difference data DF related to multiple rows of light-receiving pixels P. The signal processor 15 is configured to output such an image signal Spic.

The imaging controller 18 is configured to control the operation of the imaging device 1000 by supplying control signals to the driver 12, the reference signal generator 13, the reader 20, and the signal processor 15 and controlling the operations of these circuits. A control signal Sctl is supplied to the imaging controller 18 from the outside. This control signal Sctl includes, for example, information about the zoom magnification of so-called electronic zoom. The imaging controller 18 is configured to control the operation of the imaging device 1000 based on the control signal Sctl.

Here, the light-receiving pixel P corresponds to a specific example of a “light-receiving pixel” in the present disclosure. The pixel pair 90 corresponds to a specific example of a “pixel pair” in the present disclosure. The pixel block 100 corresponds to a specific example of a “pixel block” in the present disclosure. For example, the pixel block 100Gr corresponds to a specific example of a “first pixel block” in the present disclosure. For example, the pixel block 100R corresponds to a specific example of a “second pixel block” in the present disclosure. The lens 101 corresponds to a specific example of “lens” in the present disclosure. The control line TRGL corresponds to a specific example of a “control line” in the present disclosure. The insulating layer 113 corresponds to a specific example of an “insulating layer” in the present disclosure.

In the following, a readout driving example will be described in which the node FD has a small capacitance and the stored charges generated by light reception by each photodiode PD are digitally converted. That is, the transistor FDG (see FIG. 4) is in an off state, and the capacitance of the node FD is the capacitance of only the first floating diffusion FD1. Here, focusing on a certain pixel block 100Gr, a readout operation for ten light-receiving pixels PGr in this pixel block 100Gr will be described. Since the first floating diffusion FD1 has a smaller capacitance than the second floating diffusion FD2, the sensitivity to the same amount of stored charges is higher than when the first floating diffusion FD1 and the second floating diffusion FD2 are used.

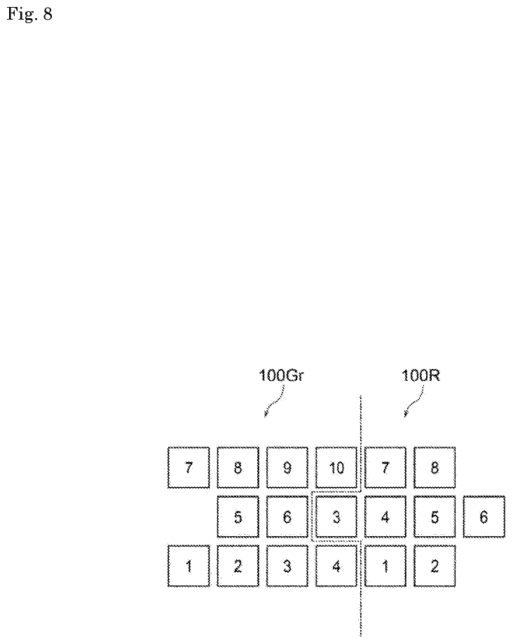

FIG. 8 is a diagram schematically showing an example of arrangement of ten pixels of the pixel block 100Gr (FIG. 4) and eight pixels of the pixel block 100R (FIG. 5).

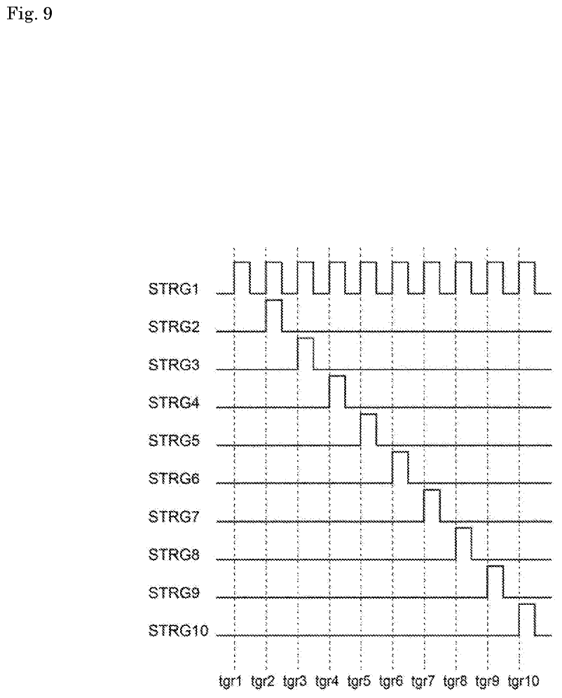

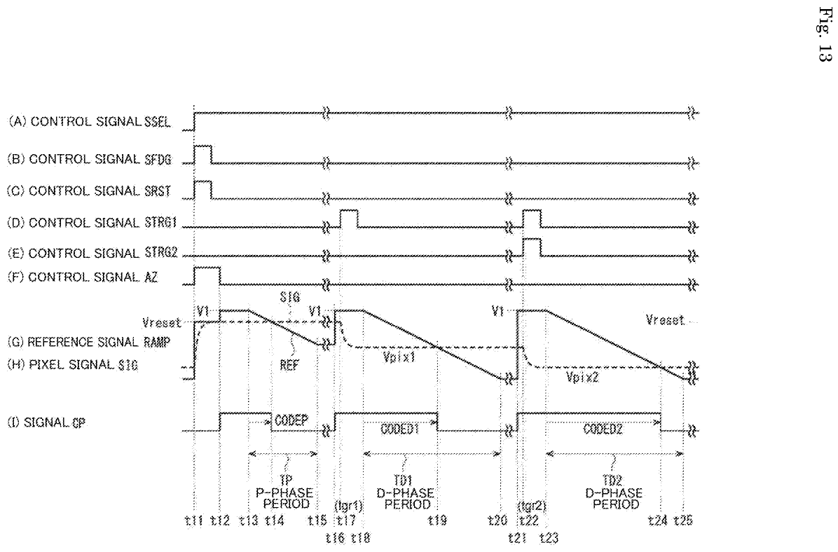

FIG. 9 is a diagram illustrating an example of a timing chart for readout driving of ten pixels of the pixel block 100Gr (FIG. 4). The horizontal axis indicates time, and the vertical axis indicates control signals STRG1 to STRG10. Note that more detailed driving timing will be described later using FIG. 13.

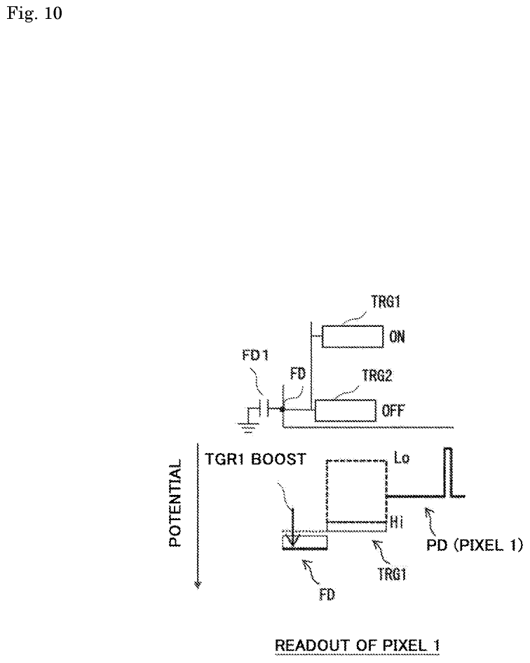

FIG. 10 is a diagram schematically showing the potentials of the node FD, the transistor TRG1, and the photodiode PD of the pixel 1 when the control signal STRG1 goes high, that is, has a high potential at time tgr1. When the control signal STRG1 goes high, the transistor TRG1 enters the ON state. At this time, the potential of the transistor TRG1 changes from low (Lo) to high (Hi). At the same time, TRG1 boost is applied to the node FD due to the stray capacitance Ctr1 of the transistor TRG1, and the potential of the node FD goes higher. In this way, the stored charges due to the light reception by the photodiode PD are transferred to the first floating diffusion FD1. Since the TRG1 boost of the transistor TRG1 brings the node FD to a higher potential, the stored charges are more stably transferred to the first floating diffusion FD1. Note that boost according to the present embodiment means adding a positive potential to a predetermined location, for example, an FD node. For example, adding a boost of 0.5 volts means increasing the positive potential at a predetermined location by an additional 0.5 volts.

Referring again to FIG. 9, when the control signal STRG1 goes low (Lo), the transistor TRG1 is turned off. At time tgr2, the control signal STRG1 goes high again, and the control signal STRG2 also goes high at the same time.

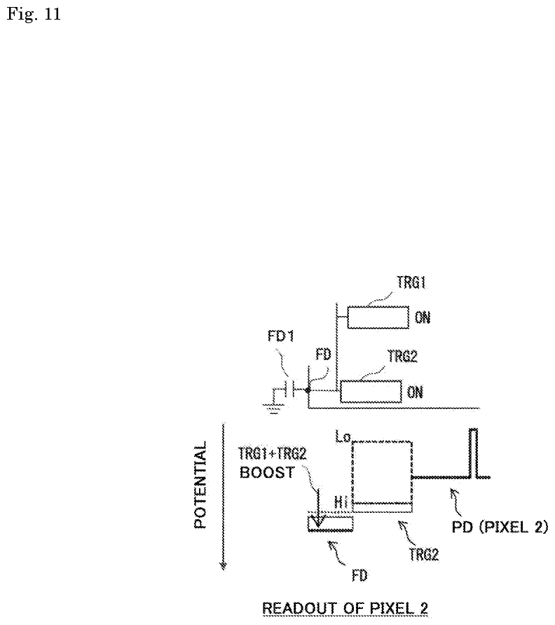

FIG. 11 is a diagram schematically showing the potentials of the node FD, the transistor TRG2, and the photodiode PD of the pixel 2 when the control signals STRG1 and STRG1 go high at time tgr2. When the control signal STRG1 goes high, the transistors TRG1 and TRG2 enter the ON state. At this time, the potentials of the transistors TRG1 and TRG2 change from low (Lo) to high (Hi). At the same time, a TRG1 boost of the stray capacitance Ctr1 of the transistor TRG1 and a TRG2 boost of the stray capacitance Ctr2 of the transistor TRG2 are applied to the node FD, and the potential of the node FD has a higher potential. In this way the stored charges due to light reception by the photodiode PD (pixel 2) and the stored charges due to light reception by the photodiode PD (pixel 1) are transferred to the first floating diffusion FD1. Since the TRG1 boost of the transistor TRG1 and the TRG2 boost of the transistor TRG2 bring the node FD to a higher potential, the stored charges are more stably transferred to the first floating diffusion FD1.

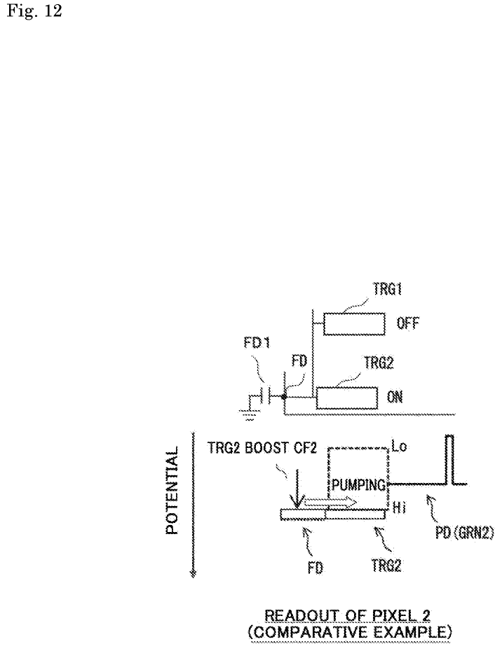

As described above, the pixel block 100Gr (FIG. 4) is densely packed, and the stray capacitance Ctr2 of the transistor TRG2 may not be large enough. FIG. 12 is a diagram schematically showing the potentials of the node FD, the transistor TRG2, and the photodiode PD of the pixel 2 when only the control signal STRG1 goes high at time tgr2. Here, a case will be exemplified in which the TRG2 boost of the transistor TRG2 is not sufficiently large. Similarly to FIG. 11, the transistor TRG2 where the control signal STRG2 goes high enters the ON state. At this time, the potential of the transistor TRG2 changes from low (Lo) to high (Hi). At the same time, although only the TRG2 boost of the transistor TRG2 is applied to the node FD, since the stray capacitance Ctr2 of TRG2 is smaller than the stray capacitance Ctr1 in the comparative example than in the example of FIG. 10, the increase in the potential of the node FD is smaller than in the example of FIG. 10. Therefore, a part of the stored charges transferred to the first floating diffusion FD1 may return to the transistor TRG1 side due to a so-called pumping phenomenon. As a result, when the transistor TRG2 enters the OFF state, there is a possibility that the charge flows back to the photodiode PD (pixel 2).

On the other hand, in the example of FIG. 11, since the control signals STRG1 and STRG1 go high at the same time, it is possible to apply the TRG1 boost of the transistor TRG1 and the TRG2 boost of the transistor TRG2 to the node FD. Therefore, even if the TRG2 boost of the transistor TRG2 is not large enough, the potential of the node FD can be made higher by using the TRG1 boost of the transistor TRG1. In this way the so-called pumping phenomenon can be suppressed.

Referring again to FIG. 9, when the control signals STRG1 and STRG2 go low (Lo), the transistors TRG1 and TRG2 are turned off. At time tgr3, the control signal STRG1 goes high again, and the control signal STRG3 also goes high at the same time. As a result, in the pixel 3 as well, the node FD has a higher potential due to the TRG1 boost of the transistor TRG1 and the TRG3 boost of the transistor TRG3, similarly to FIG. 11. Therefore, the stored charges are more stably transferred to the first floating diffusion FD1. Similar driving can be performed for the subsequent pixels 4 to 10. As a result, since the potential of the node FD has a higher potential in the pixels 4 to 10 as well, the stored charges are more stably transferred to the first floating diffusion FD1.

FIG. 13 is a diagram showing an example of a detailed readout driving timing chart for ten pixels in the pixel block 100Gr (FIG. 4). The horizontal axis indicates time, and the vertical axis indicates control signals SSEL, SFDG, SRST, STRG1, STRG2, AZ, reference signal RAMP, pixel signal SIG, and signal CP. That is, (A) shows the waveform of the control signal SSEL, (B) shows the waveform of the control signal SFDG, (C) shows the waveform of the control signal SRST, (D) shows the waveform of the control signal STRG1, (E) shows the waveform of the control signal STRG2, (F) shows the waveform of the control signal AZ, (G) shows the waveform of the reference signal RAMP, (H) shows the waveform of the pixel signal SIG, and (I) shows the waveform of signal CP. Note that times trg1 and trg2 in FIG. 9 correspond to t17 and t22.

In FIGS. 13(G) and 13(H), the waveforms of the reference signal RAMP and the signal SIG are shown using the same voltage axis. In addition, in this explanation, the waveform of the reference signal RAMP shown in FIG. 13(G) is the waveform of the voltage supplied to the input terminal of the comparator circuit 24 via the capacitive element 23, and the waveform of the signal SIG shown in FIG. 13(H) is the waveform of the voltage supplied to the input terminal of the comparator circuit 24 via the capacitive element 22.

First, at timing t11, the horizontal period H starts. In this way, the driver 12 changes the voltage of the control signal SSEL from a low level to a high level (FIG. 13(A)). As a result, in the pixel block 100Gr, the transistor SEL is turned on, and the pixel block 100Gr is electrically connected to the signal line VSL. Furthermore, at this timing t11, the driver 12 changes the voltages of the control signals SFDG and SRST from a low level to a high level (FIGS. 13(B) and 13(C)). As a result, in the pixel block 100Gr, the transistors FDG and RST are turned on, and the voltage of the first floating diffusion FD1 is set to the power supply voltage VDD (reset operation).

Then, the pixel block 100Gr outputs a voltage corresponding to the voltage of the first floating diffusion FD1 at that time. At this timing t11, the imaging controller 18 changes the voltage of the control signal AZ from a low level to a high level (FIG. 13(F)). In this way, the comparator circuit 24 of the AD converter ADC sets the operating point by setting the voltages of the capacitive elements 22 and 23. In this way, the voltage of the signal SIG is set to the reset voltage Vreset, and the voltage of the reference signal RAMP is set to the same voltage as the voltage (reset voltage Vreset) of the signal SIG (FIGS. 13(G) and 13(H)).

Then, at a timing when a predetermined time has elapsed from timing t11, the driver 12 changes the voltages of the control signals SFDG and SRST from a high level to a low level (FIGS. 13(B) and 13(C)). As a result, in the pixel block 100Gr, the transistor RST is turned off, and the reset operation ends.

Next, at timing t12, the imaging controller 18 changes the voltage of the control signal AZ from a high level to a low level (FIG. 13(F)). In this way, the comparator circuit 24 ends setting the operating point.

At this timing t12, the reference signal generator 13 sets the voltage of the reference signal RAMP to the voltage V1 (FIG. 13(G)). As a result, since the voltage of the reference signal RAMP goes higher than the voltage of the signal SIG, the comparator circuit 24 changes the voltage of the signal CP from a low level to a high level (FIG. 13(I)).

Then, during a period from timing t13 to t15 (P-phase period TP), the AD converter ADC performs AD conversion based on the signal SIG. Specifically, first, at timing t13, the reference signal generator 13 starts reducing the voltage of the reference signal RAMP from the voltage V1 by a predetermined degree of change (FIG. 13(G)). Furthermore, at this timing t13, the imaging controller 18 starts generating the clock signal CLK. The counter 25 of the AD converter ADC counts the pulses of the clock signal CLK by performing a counting operation.

Then, at timing t14, the voltage of the reference signal RAMP is lower than the voltage (reset voltage Vreset) of the signal SIG (FIGS. 13(G) and 13(H)). As a result, the comparator circuit 24 of the AD converter ADC changes the voltage of the signal CP from a high level to a low level (FIG. 13(G)). The counter 25 of the AD converter ADC stops the counting operation based on this transition of the signal CP. The count value (count value CNTP) of the counter 25 at that time is a value corresponding to the reset voltage Vreset. The latch 26 holds this count value CNTP. Then, the counter 25 resets the count value.

Next, at timing t15, the imaging controller 18 stops generating the clock signal CLK with the end of the P-phase period TP. The reference signal generator 13 stops changing the voltage of the reference signal RAMP at this timing t15 (FIG. 13(G)). Then, in the period after timing t15, the reader 20 supplies the count value CNTP held in the latch 26 to the signal processor 15 as the image signal Spic0.

Next, at timing t16, the imaging controller 18 sets the voltage of the reference signal RAMP to the voltage V1 (FIG. 13(G)). As a result, since the voltage of the reference signal RAMP goes higher than the voltage (reset voltage Vreset) of the signal SIG, the comparator circuit 24 changes the voltage of the signal CP from a low level to a high level (FIG. 13(I)).

Next, at timing t17 (trg1 in FIG. 9), the driver 12 changes the voltage of the control signal STRG1 from a low level to a high level (FIG. 13(D)). As a result, in the pixel 1, the transistor TRG1 is turned on, and the charges generated in the photodiode PD are transferred to the first floating diffusion FD1 (charge transfer operation). Then, the pixel block 100Gr outputs a voltage corresponding to the voltage of the first floating diffusion FD1 at that time. In this way the voltage of the signal SIG is the pixel voltage Vpix1 (FIG. 13(H)).

Then, at a timing when a predetermined time has elapsed from this timing t17, the driver 12 changes the voltage of the control signal STRG1 from a high level to a low level (FIG. 13(D)). As a result, in the pixel 1, the transistor TRG1 is turned off, and the charge transfer operation ends.

Then, during the period from timing t18 to timing t20 (D-phase period TD1), the AD converter ADC performs AD conversion based on the signal SIG. Specifically first, at timing t18, the reference signal generator 13 starts reducing the voltage of the reference signal RAMP from the voltage V1 by a predetermined degree of change (FIG. 13(G)). At this timing t18, the imaging controller 18 starts generating the clock signal CLK. The counter 25 of the AD converter ADC counts the pulses of the clock signal CLK by performing a counting operation.

Then, at timing t19, the voltage of the reference signal RAMP is lower than the voltage (pixel voltage Vpix1) of the signal SIG (FIGS. 13(G) and 13(H)). As a result, the comparator circuit 24 of the AD converter ADC changes the voltage of the signal CP from a high level to a low level (FIG. 13(G)). The counter 25 of the AD converter ADC stops the counting operation based on this transition of the signal CP. The count value (count value CNTD1) of the counter 25 at that time is a value corresponding to the pixel voltage Vpix1. The latch 26 holds this count value CNTD1. Then, the counter 25 resets the count value.

Next, at timing t20, the imaging controller 18 stops generating the clock signal CLK with the end of the D-phase period TD1. The reference signal generator 13 stops changing the voltage of the reference signal RAMP at this timing t20 (FIG. 13(G)). Then, in the period after this timing t20, the reader 20 supplies the count value CNTD1 held in the latch 26 to the signal processor 15 as the image signal Spic0.

Next, at timing t21, the imaging controller 18 sets the voltage of the reference signal RAMP to the voltage V1 (FIG. 13(G)). As a result, since the voltage of the reference signal RAMP goes higher than the voltage (pixel voltage Vpix1) of the signal SIG, the comparator circuit 24 changes the voltage of the signal CP from a low level to a high level (FIG. 13(G)).

Next, at timing t22 (trg2 in FIG. 9), the driver 12 changes the voltages of the control signals STRG1 and STRG2 from a low level to a high level (FIGS. 13(D) and 13(E)). As a result, in the pixel 1 and pixel 2 in the pixel block 100Gr, the transistors TRG1 and TRG2 are turned on, and the charges generated in the respective photodiodes PD are transferred to the first floating diffusion FD1 (charge transfer operation). Then, the pixel block 100Gr outputs a voltage corresponding to the voltage of the first floating diffusion FD1 at that time. In this way the voltage of the signal SIG is the pixel voltage Vpix2 (FIG. 13(H)).

Then, at a timing when a predetermined time has elapsed from this timing t22, the driver 12 changes the voltages of the control signals STRG1 and STRG2 from a high level to a low level, respectively (FIGS. 13(D) and 13(E)). As a result, transistors TRG1 and TRG2 are turned off in pixel 1 and pixel 2, and the charge transfer operation ends.

Then, during the period from timing t23 to timing t25 (D-phase period TD2), the AD converter ADC performs AD conversion based on the signal SIG. Specifically first, at timing t23, the reference signal generator 13 starts reducing the voltage of the reference signal RAMP from the voltage V1 by a predetermined degree of change (FIG. 13(G)). At this timing t23, the imaging controller 18 starts generating the clock signal CLK. The counter 25 of the AD converter ADC counts the pulses of the clock signal CLK by performing a counting operation.

Then, at timing t24, the voltage of the reference signal RAMP is lower than the voltage (pixel voltage Vpix2) of the signal SIG (FIGS. 13(G) and 13(H)). As a result, the comparator circuit 24 of the AD converter ADC changes the voltage of the signal CP from a high level to a low level (FIG. 13(G)). The counter 25 of the AD converter ADC stops the counting operation based on this transition of the signal CP. The count value (count value CNTD2) of the counter 25 at that time is a value corresponding to the pixel voltage Vpix2. The latch 26 holds this count value CNTD2. Then, the counter 25 resets the count value.

Next, at timing t25, the imaging controller 18 stops generating the clock signal CLK with the end of the D-phase period TD2. The reference signal generator 13 stops changing the voltage of the reference signal RAMP at this timing t25 (FIG. 13(G)). Then, in the period after this timing t25, the reader 20 supplies the count value CNTD2 held in the latch 26 to the signal processor 15 as the image signal Spic0.

Next, as shown in FIG. 9, the processing equivalent to that in timings t21 to t25 is continued by setting control signals STRG3 to STRG10 to a high level instead of the control signal STRG2.

In this way, the reader 20 supplies the image signal Spic0 including the count values CNTP, CNTD1, and CNTD2 to the signal processor 15. For example, the signal processor 15 generates the pixel value VGr1 of pixel 1 and the pixel value VGr2 of pixel 2 shown in FIG. 8 based on the count values CNTP, CNTD1, and CNTD2 included in the image signal Spic0 using the principle of correlated double sampling. Specifically the signal processor 15 generates the pixel value VGr1 by subtracting the count value CNTP from the count value CNTD1, for example. Since the count value CNTD1 is a value corresponding to the amount of light received by the pixel 1, the signal processor 15 can generate the pixel value VGr1 based on this count value CNTD1. Similarly the signal processor 15 generates the pixel value VGr2 by subtracting the count value CNTD1 from the count value CNTD2, for example. Since the count value CNTD2 is a value corresponding to the sum of the amounts of light received by the pixel 1 and the pixel 2, the signal processor 15 can generate the pixel value VGr2 based on this count value CNTD2. By repeating such processing, the pixel value VGr10 can be generated from the pixel value VGr3 of pixels 3 to 10.

Although the pixel block 100Gr has been described above, the same applies to the pixel blocks 100R, 100Gb, and 100B. In this way the signal processor 15 generates image data including information on pixel values for each pixel.

As described above, according to the present embodiment, when reading stored charges from the photodiode PD of one pixel (pixel 2), the transistor TRG1 of the other pixel (pixel 1) is also turned on. In this way it is possible to add a TRG1 boost of the stray capacitance Ctr1 of the transistor TRG1 and a TRG2 boost of the stray capacitance Ctr2 of the transistor TRG2 to the node FD. Therefore, even if the stray capacitance Ctr2 of the transistor TRG2 is not large enough, the potential of the node FD can be made higher by using the TRG1 boost of the transistor TRG1. In this way, the so-called pumping phenomenon can be suppressed. In this way, by increasing the density of pixels, the so-called pumping phenomenon can be suppressed even when sufficiently large stray capacitances Ctr1 to Ctr10 are not obtained.

### Second Embodiment

The imaging device 1000 according to the second embodiment differs from the imaging device 1000 according to the first embodiment in that the VSL boost applied to the node FD can also be controlled by controlling the voltage of the VSL signal line. Below, differences from the imaging device 1000 according to the first embodiment will be explained.

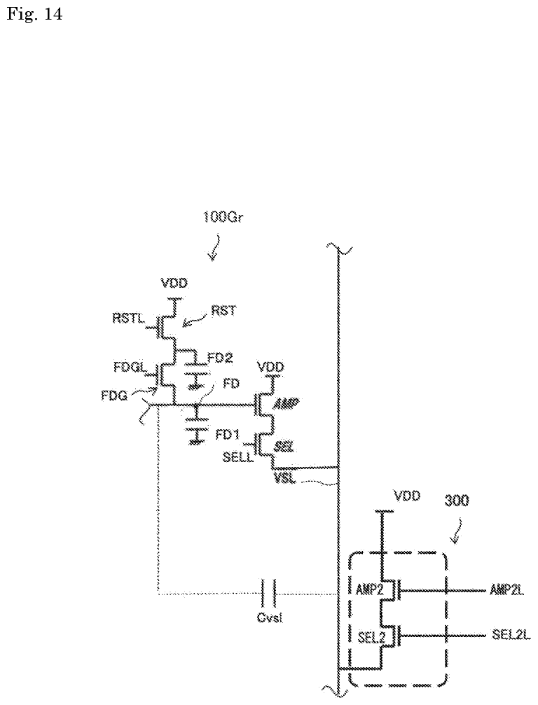

FIG. 14 is a diagram showing an example of the configuration of a part of a pixel block 100Gr according to the second embodiment. As shown in FIG. 14, a voltage control circuit 300 is provided on the VSL signal line. The voltage control circuit 300 includes transistors AMP2 and SEL2. The gate of the amplification transistor AMP2 is connected to the control line AMP2L, the drain is supplied with the power supply voltage VDD, and the source is connected to the drain of the selection transistor SEL2. The gate of the selection transistor SEL2 is connected to the control line SEL2L, the drain is connected to the source of the amplification transistor AMP, and the drain is connected to the vertical signal line VSL. Furthermore, as shown in FIG. 14, a stray capacitance Cvsl is illustrated between the node FD and the control line VSL.

The driver 12 supplies the control signal SAMP2L to the control line AMP2L, and supplies the control signal SSEL2 to the control line SEL2L.

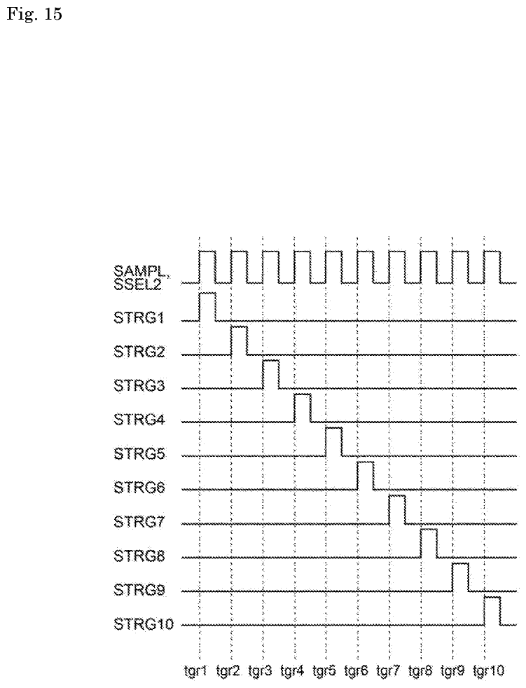

Similarly to FIG. 9, FIG. 15 is a diagram showing an example of a timing chart for readout driving of ten pixels in the pixel block 100Gr (FIG. 4). The horizontal axis indicates time, and the vertical axis indicates control signals SAMP2L, SEL2L, and STRG1 to STRG10. In FIG. 15, the control signals SAMP2L and SEL2L are drawn on the same line because they move in the same way.

When the control signal STRG1 goes high at time tgr1, the transistor TRG1 enters the ON state. At this time, the control signals SAMP2L and SEL2L also go high, and the transistors AMP2 and SEL2 also enter the ON state. As a result, the signal line VSL has a high potential, the VSL boost of the stray capacitance Cvsl is further applied to the node FD, and the node FD has a higher potential. In this way, the stored charges due to the light reception by the photodiode PD in the pixel 1 are transferred to the first floating diffusion FD1. Since the VSL boost brings the node FD to a higher potential, the stored charges are more stably transferred to the first floating diffusion FD1. Through a similar operation, the stored charges due to light reception by the photodiode PD in the pixels 2 to 10 are transferred to the first floating diffusion FD1. In addition, in the transfer of the stored charges from the pixel 2 to the pixel 10, it is also possible to control the TRG1 boost of the stray capacitance Ctr1 of the transfer transistor TRG1 (see FIG. 4) to be applied to the node FD.

Driving similar to that shown in FIG. 13 is performed, and based on the count values CNTP, CNTD1, and CNTD2, the pixel value VGr1 of pixel 1 and the pixel value VGr2 of pixel 2 shown in FIG. 8 are generated. In the imaging device 1000 according to the second embodiment, since the transistor TRG1 enters the OFF state when reading out the photodiode PD in the pixels 2 to 10, the signal calculation method is different from that in the imaging device 1000 according to the first embodiment.

More specifically the pixel value VGr1 of pixel 1 and the pixel value VGr2 of pixel 2 shown in FIG. 8 are generated based on the count values CNTP, CNTD1, and CNTD2 (see FIG. 13) using the principle of correlated double sampling. The signal processor 15 generates the pixel value VGr1 by subtracting the count value CNTP from the count value CNTD1, for example. Since the count value CNTD1 is a value corresponding to the amount of light received by the pixel 1, the signal processor 15 can generate the pixel value VGr1 based on this count value CNTD1. Similarly the signal processor 15 generates the pixel value VGr2 by subtracting the count value CNTP from the count value CNTD2, for example. Since the count value CNTD2 is a value corresponding to the amount of light received by the pixel 2, the signal processor 15 can generate the pixel value VGr3 based on this count value CNTD2. By repeating such processing, pixel values VGr3 to VGr10 of pixels 3 to 10 can be generated.

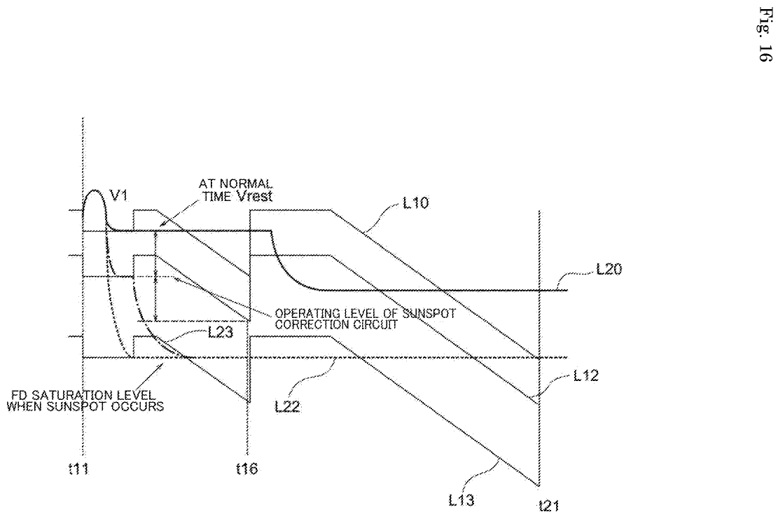

FIG. 16 is a diagram illustrating an operation example when driving the voltage control circuit 300 as a sunspot correction circuit. The line L10 has the same voltage as the reference RAMP from time t11 to t21 in FIG. 13. The line L20 has the same voltage as the pixel signal SID.

Lines L12 and L13 are diagrams in which line L10 is vertically shifted for convenience of explanation. When an ultra-high brightness object such as sunlight is imaged, the charges in the photodiode PD leak even when the transistors TRG1 to TRG10 are turned off, and charges are stored up to the storage limit of the first floating diffusion FD1. The pixel signal SID in such a case has a saturation curve L22. In this case, the potential of the first floating diffusion FD1 already reaches its maximum value during the period when the control signal AZ is high (see FIG. 13). Therefore, the counter CODEP reaches its full range. Similarly the counter CODED1 also reaches its full range. As a result, the difference between the counter CODEP and the counter CODED1 is 0, and a pixel value is generated as black. Such a phenomenon is called a sunspot phenomenon.

Therefore, when the potential of the first floating diffusion FD1 exceeds the reset voltage Vreset during the period when the control signal AZ is high as shown in the saturation curve L22 (see FIG. 13), the transistors AMP2 and SEL2 are controlled to enter the ON state and the potential during the P-phase period is supplied to the signal line VLS as V1, for example. As a result, as shown in line L23, the potential at the P phase is V1, the counter CODEP has a value equivalent to V1, the difference between the counter CODEP and the counter CODED1 is the high-intensity pixel value, and the pixel value is generated as white. In this way, the voltage control circuit 300 can also be driven as a sunspot correction circuit.

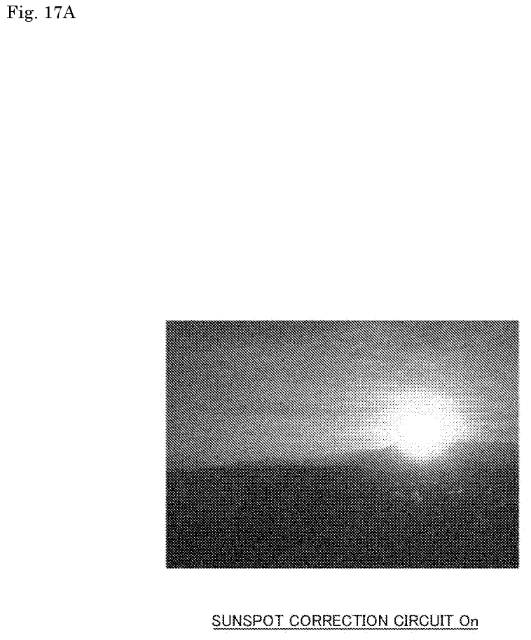

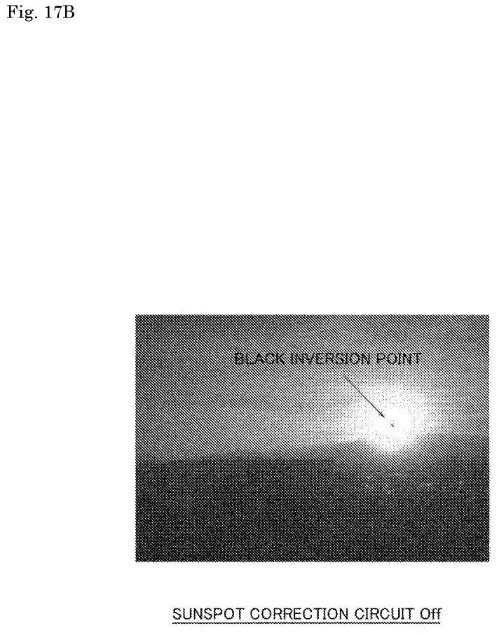

FIG. 17A is a solar image in which the voltage control circuit 300 is driven as a sunspot correction circuit, and FIG. 17B is a solar image in which the voltage control circuit 300 is not driven as a sunspot correction circuit. It can be seen that sunspots occur when the voltage control circuit 300 is not driven as a sunspot correction circuit, but no sunspots occur when the voltage control circuit 300 is driven as a sunspot correction circuit.

As described above, according to the present embodiment, when reading stored charges from the photodiode PD of one pixel, the potential of the signal line VLS is increased. In this way, the potential of the node FD can be made higher by the VSL boost of the stray capacitance Cvsl between the node FD and the control line VSL. In this way, the so-called pumping phenomenon can be suppressed.

Therefore, the so-called pumping phenomenon can be suppressed even when sufficiently large stray capacitances Ctr1 to Ctr10 are not obtained due to the high density of pixels.

### Third Embodiment

The imaging device 1000 according to the third embodiment is different from the imaging device 1000 according to the second embodiment in that the boost applied to the node FD can also be controlled by the RST boost of the stray capacitance Crst between the gate of the transistor RST and the node FD. Below, differences from the imaging device 1000 according to the second embodiment will be explained.

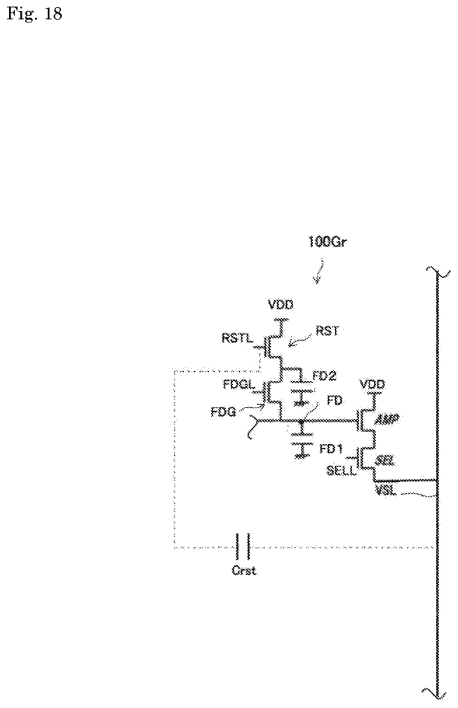

FIG. 18 is a diagram showing an example of the configuration of a part of a pixel block 100Gr according to the second embodiment. As shown in FIG. 18, a stray capacitance Crst is illustrated between the gate of the transistor RST and the node FD.

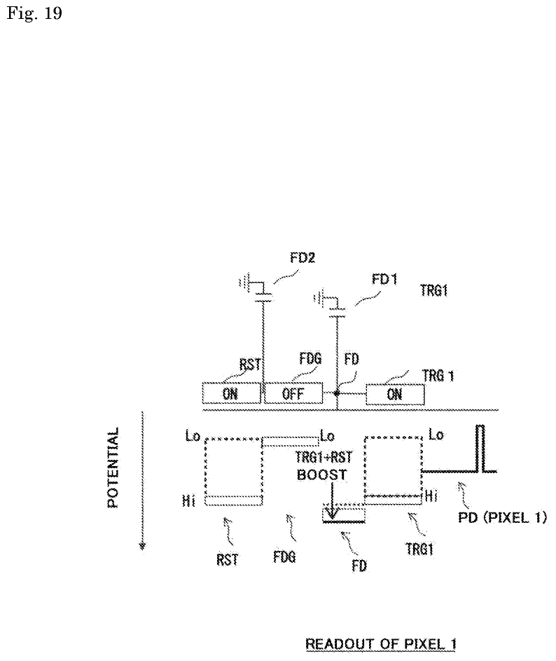

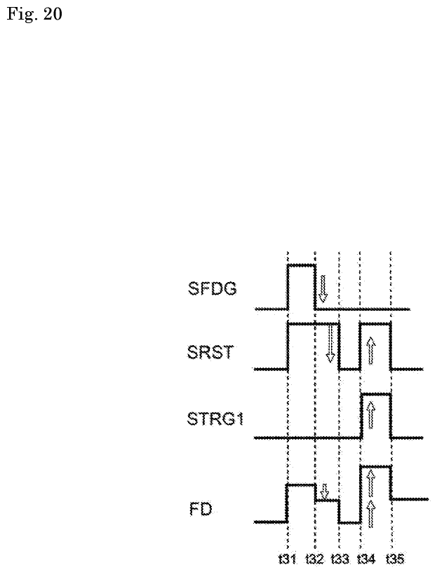

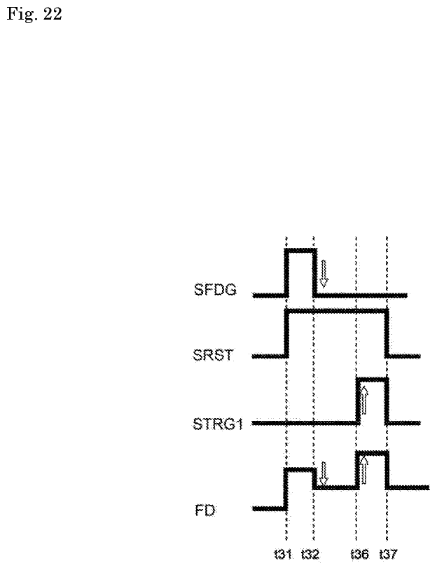

FIG. 19 is a diagram schematically showing the potentials of the node FD, the transistors TRG1, FDG, RST, and the photodiode PD of the pixel 1. The positions of the transistors RST, FDG, the node FD, and the transistor TRG1 are schematically shown on the upper side, and the corresponding potentials are schematically shown on the lower side. Low (Lo) indicates that the corresponding gate signal is low (Lo), and high (Hi) indicates that the corresponding gate signal is high (Hi). That is, here, a state between timings t34 and t35 in FIG. 20, which will be described later, and a state between timings t36 and t37 in FIG. 22, which will be described later, are schematically shown.

FIG. 20 is a timing chart showing an example of charge readout driving from the pixel 1. The horizontal axis indicates time, and the vertical axis indicates potentials of control signals SFDG, SRST, STRG1 and node FD. As shown in FIG. 20, when the control signals SFDG and SRST simultaneously go high (Hi) at timing t31, the first floating diffusion FD1 and the second floating diffusion FD2 have the potential VDD and are reset. When the control signal SFDG goes low (Lo) at timing t32, the transistor FDG is turned off, and the second floating diffusion FD2 is separated from the node FD. At this time, the potential of the node FD decreases due to the feed-through of the transistor FDG.

When the control signal SRST goes low (Lo) at timing t33, the transistor RST is turned off and the supply of the power supply VDD is stopped. At this time, the potential of the node FD decreases due to the feed-through of the transistor RST. When the control signals SRST and STRG1 go high (Hi) simultaneously at timing t34, the transistors RST and TRG1 are turned on. At this time, the TRG1 boost of the boost capacitance Ctr1 of the transistor TRG1 and the RST boost of the boost capacitance Crst of the transistor RST are added, the node FD has a high potential, and the stored charges are transferred from the photodiode PD of the pixel 1 (pixel 1) to the first floating diffusion FD1. In this way, the RST boost is added to the TRG1 boost, and the stored charges can be more stably transferred to the first floating diffusion FD1.

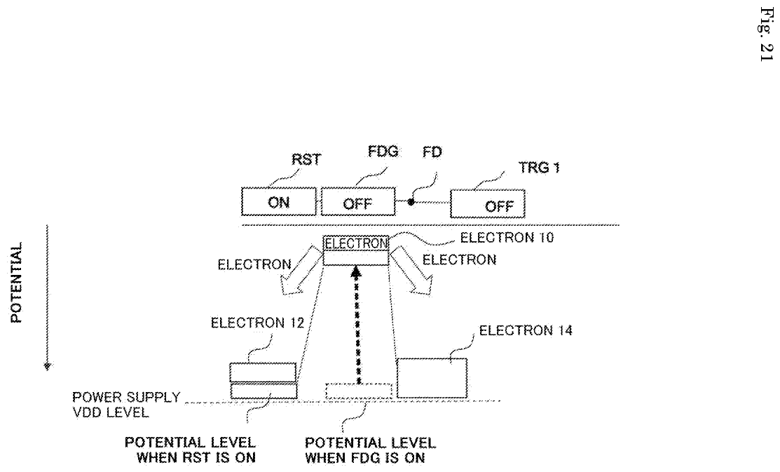

FIG. 21 is a diagram schematically showing the movement state of electrons under the gate of the transistor FDG. Here, the state between timings t32 and t33 in FIG. 20 is shown. When the transistor FDG is turned off, a phenomenon occurs in which the electrons 10 remaining under the gate of the transistor FDG flow to both sides. This phenomenon is called channel charge injection. This channel charge injection forms part of the feed-through in order to lower the potential of the node FD. At this time, since the transistor RST is in the on state, the electrons 12 flowing to the transistor RST side are discharged to the power supply VDD. This suppresses the feed-through. If the transistor RST and the transistor FDG are turned off at the same time, there is a possibility that the charges flowing to the transistor RST side may return to the node FD side, resulting in an increase in the feed-through. In other words, deterioration in transfer to the node FD occurs. In this manner, since the transistor RST is in the on state when the transistor FDG is turned off, the electrons 12 flowing to the transistor RST side are discharged to the power supply VDD, and the feed-through is suppressed.

FIG. 22 is a timing chart showing another example of charge readout driving from the pixel 1. The horizontal axis indicates time, and the vertical axis indicates the potentials of control signals SFDG, SRST, STRG1 and node FD. As shown in FIG. 21, when the control signals SFDG and SRST simultaneously go high (Hi) at timing t31, the first floating diffusion FD1 and the second floating diffusion FD2 has the potential VDD and are reset. At this time, the RST boost of the boost capacitance Crst of the transistor RST is applied to the node FD.

When the control signal SFDG goes low (Lo) at timing t32, the transistor FDG is turned off, and the second floating diffusion FD2 is separated from the node FD. At this time, the potential of the node FD decreases due to the feed-through of the transistor FDG.

When the control signal STRG1 goes high (Hi) at timing t36, the transistor TRG1 is turned on. At this time, the boost of TRG1 by the boost capacitance Ctr1 of the transistor TRG1 is further applied to the node FD, the node FD has a high potential, and the stored charges are transferred from the photodiode PD (pixel 1) of the pixel 1 to the first floating diffusion FD1. In this way the RST boost is added to the TRG1 boost, and the stored charges can be more stably transferred to the first floating diffusion FD1.

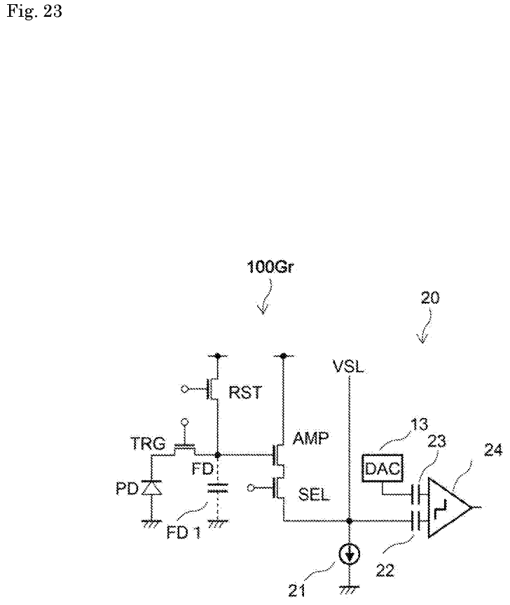

FIG. 23 is a diagram showing an example of the configuration of the pixel block 100Gr for explaining the feed-through of the transistor RST. FIG. 23 is an example without transistor FRG. Therefore, only the first floating diffusion FD1 is connected to the node FD. CTRD is the capacitance of the first floating diffusion FD1.

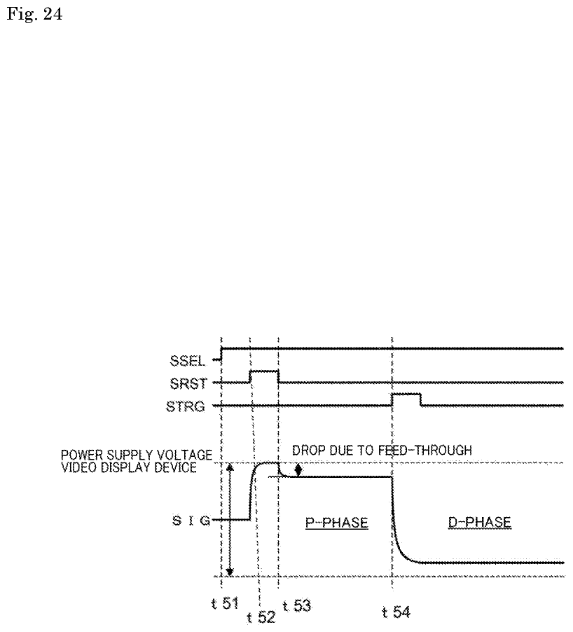

FIG. 24 is a timing chart of an example of readout driving of the pixel block 100Gr in FIG. 23. The horizontal axis indicates time. The vertical axis indicates control signals SSEL, SRST, STRG, and pixel signal SIG. At timing T51, the control signal SSEL goes high, and the pixel signal SIG corresponding to the node FD before reset is output. At timing T52, the control signal SRST goes high, and the node FD has the power supply voltage VDD. Then, at timing T53, when the control signal SRST goes low and the transistor RST is turned off, the pixel signal SIG decreases in accordance with the decrease in the potential ΔV_{FD} due to the feed-through of the transistor RST. Then, at timing T54, the control signal STRG goes high and the transistor TRG is turned on, and charges are read out from the photodiode PD.

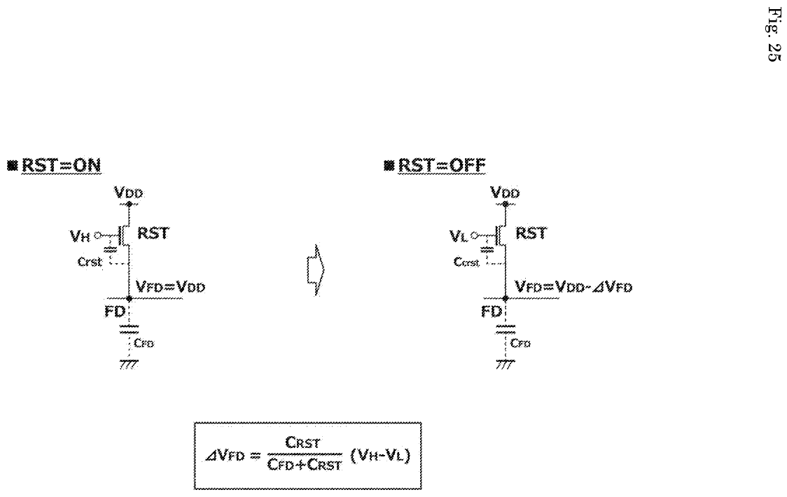

FIG. 25 is a diagram showing a further example of the configuration of a part of the pixel block 100Gr shown in FIG. 24. Astray capacitance Crst between the gate of transistor RST and the FD node is illustrated. When a high level signal V_{H} is applied to the gate of the transistor RST, the total amount of charge Q is expressed by Equation (1). On the other hand, when the low level signal V_{L} is applied to the gate of the transistor RST, the total amount of charge Q2 is expressed by Equation (2).

$$\begin{matrix}[ Math . 1 ] & \\ \begin{matrix}Q = CTRD \times V DD + Crst \times ( V DD - {V}_{H} ) \\ = CTRD \times V DD + Crst \times V DD - Crst \times {V}_{H}\end{matrix} & ( 1 )\end{matrix}$$

$$\begin{matrix}[ Math . 2 ] & \\ \begin{matrix}Q 2 = CTRD \times ( V DD - ΔV FD ) + Crst \times ( V DD - ΔV FD - {V}_{L} \\ = CTRD \times V DD + Crst \times V DD - ( CTRD + Crst ) \times ΔV FD - Crst \times {V}_{L}\end{matrix} & ( 2 )\end{matrix}$$

Since Q=Q2, a relationship expressed by Equation (3) is satisfied.

$$\begin{matrix}[ Math . 3 ] & \\ CTRD \times V DD + Crst \times V DD - CRST \times {V}_{H} = CTRD \times VDD + Crst \times VDD - ( CTRD + Crst ) \times ΔV FD - Crst \times {V}_{L} & ( 3 )\end{matrix}$$

$$( CTRD + Crst ) \times ΔV FD = Crst \times {V}_{H} - Crst \times {V}_{L}$$

Therefore Equation (4) can be obtained from these relationships.

$$\begin{matrix}[ Math . 4 ] & \\ {ΔV}_{FD} = \frac{{C}_{rST}}{\underline{{C}_{FD} + Crst}} ( {V}_{H} - {V}_{L} ) & ( 4 )\end{matrix}$$

In other words, the drop in the potential ΔV_{FD} due to the feed-through of the transistor RST is due to the distribution of the stray capacitance Crst between the gate of the transistor RST and the FD node and the capacitance CTR_{D} of the first floating diffusion FD1 and the gate voltage difference between on and off of the transistor RST.

Driving similar to that shown in FIG. 13 is performed, and based on the count values CNTP, CNTD1, and CNTD2, the pixel value VGr1 of pixel 1 and the pixel value VGr2 of pixel 2 shown in FIG. 8 are generated. In the imaging device 1000 according to the second embodiment, since the transistor TRG1 enters the OFF state when reading out the photodiode PD in the pixels 2 to 10, the signal calculation method is different from that in the imaging device 1000 according to the first embodiment.

More specifically the pixel value VGr1 of pixel 1 and the pixel value VGr2 of pixel 2 shown in FIG. 8 are generated based on the count values CNTP, CNTD1, and CNTD2 (see FIG. 13) using the principle of correlated double sampling. The signal processor 15 generates the pixel value VGr1 by subtracting the count value CNTP from the count value CNTD1, for example. Since the count value CNTD1 is a value corresponding to the amount of light received by the pixel 1, the signal processor 15 can generate the pixel value VGr1 based on this count value CNTD1. Similarly the signal processor 15 generates the pixel value VGr2 by subtracting the count value CNTP from the count value CNTD2, for example. Since the count value CNTD2 is a value corresponding to the amount of light received by the pixel 2, the signal processor 15 can generate the pixel value VGr3 based on this count value CNTD2. By repeating such processing, pixel values VGr3 to VGr10 of pixels 3 to 10 can be generated. In addition, in the transfer of the stored charges from the pixel 2 to the pixel 10, it is also possible to control the TRG1 boost of the stray capacitance Ctr1 of the transfer transistor TRG1 (see FIG. 4) to be applied to the node FD.

As described above, according to the present embodiment, the separation transistor FDG is put into the disconnected state, and the reset transistor RST is put into the connected state. As a result, the RST boost of the stray capacitance Crst between the gate of the reset transistor RST and the node FD can be applied to the node FD while the direct electrical connection between the node FD and the reset transistor RST is disconnected. That is, when reading stored charges from the photodiode PD of one pixel, the boost applied to the node FD can be controlled by the RST boost of the stray capacitance Crst between the gate of the reset transistor RST and the node FD. In this way, the potential of the node FD can be made higher by RST boost of the stray capacitance Crs between the node FD and the gate of the transistor RST. In this way the so-called pumping phenomenon can be suppressed. The separation transistor is put into a disconnected state, and the reset transistor is put into a connected state. Therefore, the so-called pumping phenomenon can be suppressed even when sufficiently large stray capacitances Ctr1 to Ctr10 are not obtained due to the high density of pixels.

### Fourth Embodiment

The imaging device 1000 according to the fourth embodiment is different from the imaging device 1000 according to the third embodiment in that it further includes driving control for reducing the boost applied to the node FD when reading stored charges of a plurality of pixels at once. Below, differences from the imaging device 1000 according to the third embodiment will be explained.

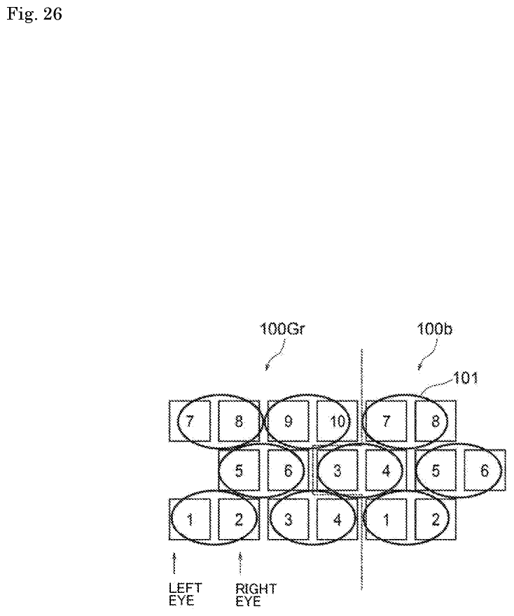

Similarly to FIG. 8, FIG. 26 is a diagram schematically showing an example of arrangement of ten pixels of the pixel block 100Gr (FIG. 4) and eight pixels of the pixel block 100R (FIG. 5). An on-chip lens 101 is arranged in each pixel pair. As will be described later, in imaging that generates an image plane phase difference, for example, stored charges of pixels 1, 3, 5, 7, and 9 of the pixel block 100Gr are acquired as a left-eye signal. On the other hand, for example, the stored charges of pixels 2, 4, 6, 8, and 10 of the pixel block 100Gr are acquired as a right-eye signal. In this case, the stored charges are, for example, about five times that of each pixel. Therefore, in the present embodiment, when reading out a plurality of pixels, the first floating diffusion FD1 and the second floating diffusion FD2 are used.

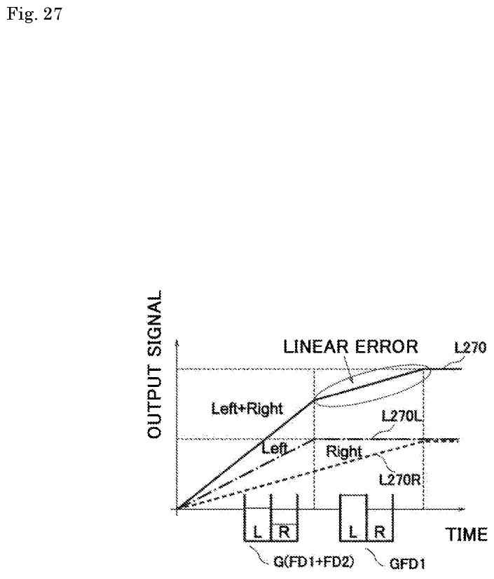

FIG. 27 is a diagram schematically showing an output signal when the first floating diffusion FD1 is used, and an output signal when the first floating diffusion FD1 and the second floating diffusion FD2 are used. The horizontal axis indicates the imaging time, and the vertical axis indicates the output signal. A figure G(FD1+FRD2) is a diagram schematically showing stored charges when the first floating diffusion FD1 and the second floating diffusion FD2 are used. The vertical axis indicates the stored charges, and the horizontal axis indicates the stored charges of pixels 1, 3, 5, 7, and 9 (see FIG. 26) and the stored charges of pixels 2, 4, 6, 8, and 10 of the pixel block 100Gr. On the other hand, a figure GFD1 is a diagram schematically showing stored charges when the first floating diffusion FD1 is used. The vertical axis indicates the stored charges, and the horizontal axis indicates the stored charges of pixels 1, 3, 5, 7, and 9 (see FIG. 26) and the stored charges of pixels 2, 4, 6, 8, and 10 of the pixel block 100Gr. As shown in the figure GFD1, when only the first floating diffusion FD1 is used, the stored charges are saturated. On the other hand, as shown in the figure G(FD1+FRD2), when the first floating diffusion FD1 and the second floating diffusion FD2 are used, it is possible to store the stored charges without saturating them.

The left-eye side output signal L270L corresponding to the stored charges of the figure GFD1 has a constant value after saturation since the stored charges are saturated even after the imaging time has elapsed. On the other hand, the right-eye side output signal L270R corresponding to the stored charges of the figure GFD1 increases almost in proportion to the imaging time since the stored charges are not saturated even after the imaging time has elapsed.

Since the output signal L270 corresponding to the stored charges obtained by adding the stored charges of the left eye and the stored charges of the right eye of the figure G(FD1+FRD2) uses the first floating diffusion FD1 and the second floating diffusion FD2, the output signal has a signal value corresponding to the imaging time. However, when a large amount of light is imaged or when the imaging time is prolonged, linearity may collapse and saturation may occur. In this way, driving may be performed to read out the stored charges of the left and right eyes at the same time, but by transferring the stored charges to the first floating diffusion FD1 and the second floating diffusion FD2, it is possible to suppress the saturation of the stored charges.

The zoom operation in the imaging device 1000 will be described below.

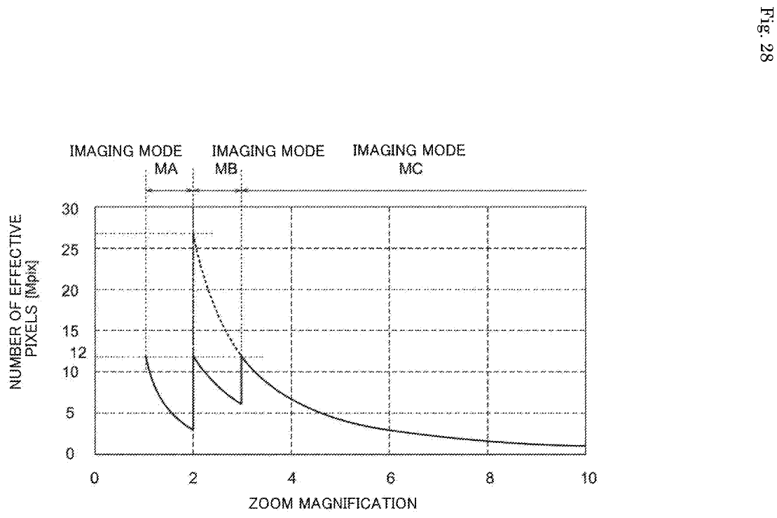

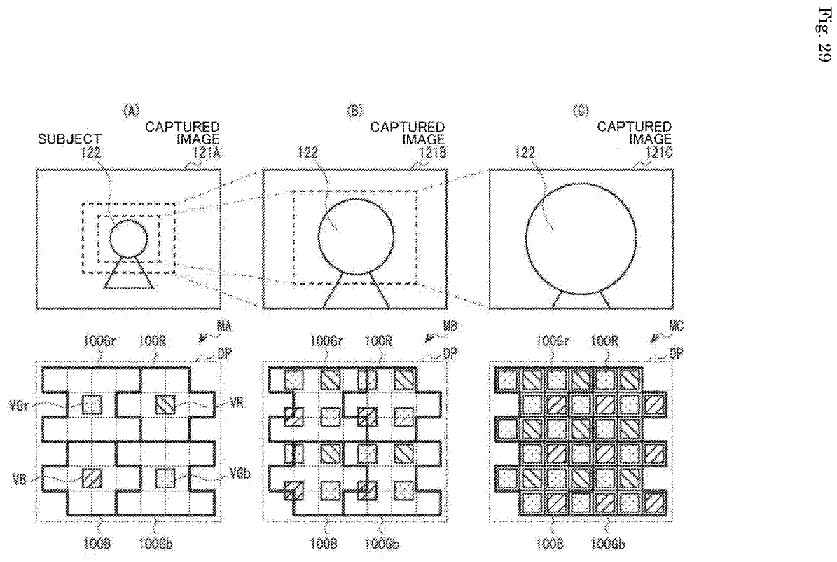

FIG. 28 is a diagram showing an example of the number of light-receiving pixels P (the number of effective pixels) related to a captured image when the zoom magnification is changed from 1× to 10×. In FIG. 28, the solid line indicates the number of effective pixels of the imaging device 1000. FIG. 29 is a diagram showing an example of a zoom operation in the imaging device 1000, in which (A) shows the operation when the zoom magnification is 1×, (B) shows the operation when the zoom magnification is 2×, and (C) shows the operation when the zoom magnification is 3×.

The imaging device 1000 has three imaging modes M (imaging modes MA, MB, and MC). The imaging controller 18 selects one of the three imaging modes MA to MC based on information about the zoom magnification included in the control signal Sctl. Specifically, as shown in FIG. 28, the imaging controller 18 selects the imaging mode MA when the zoom magnification is less than 2, selects the imaging mode MB when the zoom magnification is 2 or more and less than 3, and selects the imaging mode MC when the zoom magnification is 3 or more.

In the imaging mode MA, as shown in FIG. 29(A), the imaging device 1000 obtains four pixel values V (pixel values VR, VGr, VGb, and VB) in each of the plurality of units U. The specific operation will be described later. In this manner, the imaging device 1000 generates image data DP by generating pixel values V at a ratio of 4 with respect to thirty-six light-receiving pixels P. When the number of light-receiving pixels P in the pixel array 11 is 108 [Mpix], pixel values V for 12 [Mpix] are calculated. As a result, as shown in FIG. 28, the number of effective pixels is 12 [Mpix].

As shown in FIG. 28, in this imaging mode MA, when the zoom magnification is increased from 1, the number of effective pixels decreases in accordance with the magnification. Then, when the zoom magnification is 2, the imaging mode M is the imaging mode MB.

In the imaging mode MB, the imaging device 1000 obtains sixteen pixel values V in each of the plurality of units U, as shown in FIG. 29(C). The specific operation will be described later. In this way the imaging device 1000 generates image data DP by generating pixel values V at a ratio of 16 with respect to thirty-six light-receiving pixels P. When the number of light-receiving pixels P in the pixel array 11 is 108 [Mpix], pixel values V for 48 [Mpix] are calculated. In reality since the zoom magnification is 2×, the imaging range is narrowed to ¼ as shown in FIG. 29(C), and the number of effective pixels is 12 [Mpix](=48 [Mpix]/4).

As shown in FIG. 28, in this imaging mode MB, when the zoom magnification is increased from 2, the number of effective pixels decreases in accordance with the magnification. Then, when the zoom magnification is 3, the imaging mode M is the imaging mode MC.

In the imaging mode MC, the imaging device 1000 obtains thirty-six pixel values V in each of the plurality of units U, as shown in FIG. 29(C). The specific operation is as described in the first to third embodiments. In this way the imaging device 1000 generates image data DP by generating pixel values V at a ratio of 36 with respect to thirty-six light-receiving pixels P. When the number of light-receiving pixels P in the pixel array 11 is 108 [Mpix], 108 [Mpix] captured images can be obtained. In reality since the zoom magnification is 3×, the imaging range is narrowed to 1/9 as shown in FIG. 29(C), and the number of effective pixels is 12 [Mpix](=108 [Mpix]/9).

In this way since the imaging device 1000 is provided with three imaging modes M, it is possible to reduce changes in image quality of captured images when the zoom magnification is changed. That is, for example, if the imaging mode MB is omitted and two imaging modes MA and MC are provided, the imaging mode MA is selected when the zoom magnification is less than 2×, and the imaging mode MC is selected when the zoom magnification is 2× or more. In this case, the number of effective pixels changes greatly as indicated by the broken line in FIG. 28. That is, in this example, when the zoom magnification is 2×, the imaging mode MC is selected, and the effective number of pixels is 27 [Mpix](=108 [Mpix]/4). Therefore, since there is a large difference between the number of effective pixels when the zoom magnification is, for example, 1.9× and the number of effective pixels when the zoom magnification is 2×, there is a possibility that the image quality of captures images changes greatly when the zoom magnification is around 2×. On the other hand, since the imaging device 1000 is provided with three imaging modes M, it is possible to reduce changes in the number of effective pixels when the zoom magnification is changed. Therefore it is possible to suppress changes in the image quality of captured images.

### (Imaging Mode MA)

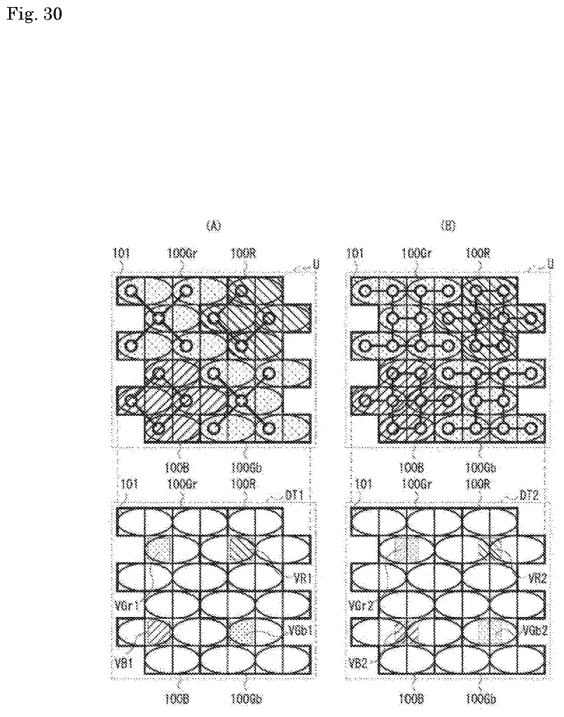

FIG. 30 is a diagram illustrating an example of the operation of the imaging device 1000 in the imaging mode MA. In FIG. 30, the light-receiving pixels P indicated by “O” indicate the light-receiving pixels P that are subject to the readout operation.

First, as shown in FIG. 30(A), the imaging device 1000 generates image data DT1 by calculating the pixel value V corresponding to the amount of light received by the left light-receiving pixel P in the pixel pair 90 provided with the lens 101 in each of the plurality of pixel blocks 100. Specifically, the imaging device 1000 calculates the pixel value VGr1 at the center of gravity of five light-receiving pixels PGr arranged on the left side in the five pixel pairs 90 among the ten light-receiving pixels PGr of the pixel block 100Gr by performing a readout operation on the five light-receiving pixels PGr. In addition, the imaging device 1000 calculates the pixel value VR1 at the center of gravity position of the four light-receiving pixel PR arranged on the left side in the four pixel pairs 90 among the eight light-receiving pixels PR of the pixel block 100R by performing a readout operation on the four light-receiving pixels PR. The imaging device 1000 calculates the pixel value VB1 at the center of gravity of the four light-receiving pixels PB arranged on the left side in the four pixel pairs 90 among the eight light-receiving pixels PB of the pixel block 100B by performing a readout operation on the four light-receiving pixels PB. The imaging device 1000 calculates the pixel value VGb1 at the center of gravity position of the five light-receiving pixels PGb arranged on the left side in the five pixel pairs 90 among the ten light-receiving pixels PGb of the pixel block 100Gb by performing a readout operation on the five light-receiving pixels PGb. In this way, the imaging device 1000 generates image data DT1 (FIG. 30(A)) including the pixel values VGr1, VR1, VB1, and VGb1.

Next, as shown in FIG. 30(B), the imaging device 1000 generates image data DT2 by calculating the pixel value V corresponding to the amount of light received by all the light-receiving pixels P in each of the plurality of pixel blocks 100. Specifically, the imaging device 1000 calculates the pixel value VGr2 at the center of gravity of the ten light-receiving pixels PGr of the pixel block 100Gr by performing a readout operation on the ten light-receiving pixels PGr. Furthermore, the imaging device 1000 calculates the pixel value VR2 at the center of gravity of the eight light-receiving pixels PR of the pixel block 100R by performing a readout operation on the eight light-receiving pixels PR. The imaging device 1000 calculates the pixel value VB2 at the center of gravity of the eight light-receiving pixels PB of the pixel block 100B by performing a readout operation on the eight light-receiving pixels PB. The imaging device 1000 calculates the pixel value VGb2 at the center of gravity of the ten light-receiving pixels PGb of the pixel block 100Gb by performing a readout operation on the ten light-receiving pixels PGb. In this way, the imaging device 1000 generates image data DT2 (FIG. 30(B)) including the pixel values VGr2, VR2, VB2, and VGb2.

Focusing on a certain pixel block 100Gr, a readout operation for ten light-receiving pixels PGr in this pixel block 100Gr will be described below.

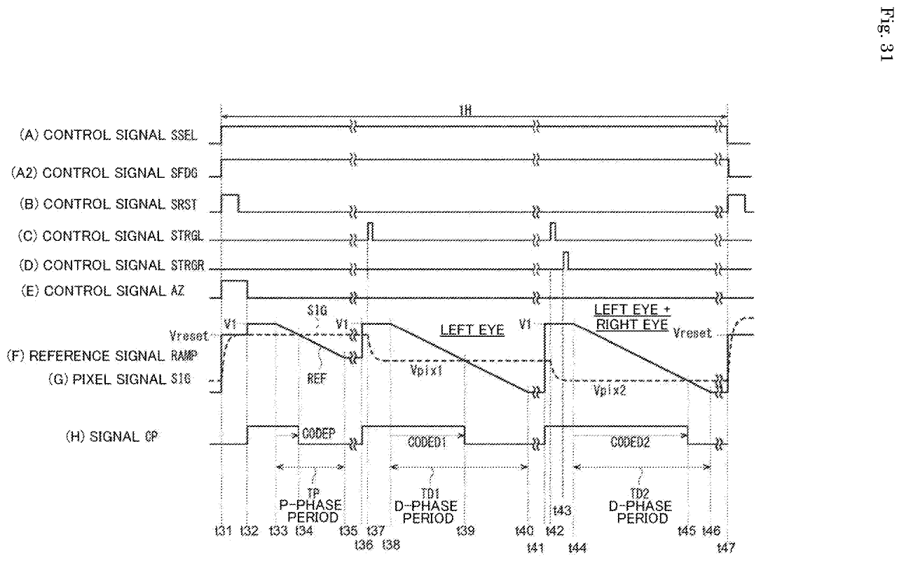

FIG. 31 is a diagram showing an example of a readout operation when generating an image plane phase difference, in which (A) shows the waveform of the control signal SSEL, (A2) shows the waveform of the control signal SFDG, (B) shows the waveform of the control signal SRST, (C) shows the waveform of the control signal STRG (control signal STRGL) supplied to the light-receiving pixel PGr arranged on the left side in the pixel pair 90, (D) shows the waveform of the control signal STRG (control signal STRGR) supplied to the light-receiving pixel PGr arranged on the right side in the pixel pair 90, (E) shows the waveform of the control signal AZ, (F) shows the waveform of the reference signal RAMP, (G) shows the waveform of the signal SIG, and (H) shows the waveform of the signal CP. In FIGS. 31(F) and 31(G), the waveforms of the reference signal RAMP and the signal SIG are shown using the same voltage axis. In addition, in this explanation, the waveform of the reference signal RAMP shown in FIG. 31(F) is the waveform of the voltage supplied to the input terminal of the comparator circuit 24 via the capacitive element 23, and the waveform of the signal SIG shown in FIG. 31(G) is the waveform of the voltage supplied to the input terminal of the comparator circuit 24 via the capacitive element 22.

First, at timing t31, the horizontal period H starts. In this way, the driver 12 changes the voltage of the control signal SSEL from a low level to a high level (FIG. 31(A)). As a result, in the pixel block 100Gr, the transistor SEL is turned on, and the pixel block 100Gr is electrically connected to the signal line VSL. At this timing t11, the driver 12 changes the voltage of the control signal SFDG from a low level to a high level (FIG. 12(A2)). In this way, both the first floating diffusion FD1 and the second floating diffusion FD2 are connected to the node FD.

Furthermore, at this timing t31, the driver 12 changes the voltage of the control signal SRST from a low level to a high level (FIG. 31(B)). As a result, in the pixel block 100Gr, the transistor RST is turned on, and the voltages of the first floating diffusion FD1 and the second floating diffusion FD2 are set to the power supply voltage VDD (reset operation). Then, the pixel block 100Gr outputs a voltage corresponding to the voltages of the first floating diffusion FD1 and the second floating diffusion FD2 at that time. At this timing t31, the imaging controller 18 changes the voltage of the control signal AZ from a low level to a high level (FIG. 31(E)). In this way, the comparator circuit 24 of the AD converter ADC sets the operating point by setting the voltages of the capacitive elements 22 and 23. In this way, the voltage of the signal SIG is set to the reset voltage Vreset, and the voltage of the reference signal RAMP is set to the same voltage as the voltage (reset voltage Vreset) of the signal SIG (FIGS. 31(F) and 31(G)).

Then, at a timing when a predetermined time has elapsed from timing t31, the driver 12 changes the voltage of the control signal SRST from a high level to a low level (FIG. 31(B)). As a result, in the pixel block 100Gr, the transistor RST is turned off, and the reset operation ends.

Next, at timing t32, the imaging controller 18 changes the voltage of the control signal AZ from a high level to a low level (FIG. 31(E)). In this way, the comparator circuit 24 ends setting the operating point.

At this timing t32, the reference signal generator 13 sets the voltage of the reference signal RAMP to the voltage V1 (FIG. 31(F)). As a result, since the voltage of the reference signal RAMP goes higher than the voltage of the signal SIG, the comparator circuit 24 changes the voltage of the signal CP from a low level to a high level (FIG. 31(H)).

Then, during the period from timing t33 to timing t35 (P-phase period TP), the AD converter ADC performs AD conversion based on the signal SIG. Specifically, first, at timing t13, the reference signal generator 13 starts reducing the voltage of the reference signal RAMP from the voltage V1 by a predetermined degree of change (FIG. 31(F)). At this timing t33, the imaging controller 18 starts generating the clock signal CLK. The counter 25 of the AD converter ADC counts the pulses of the clock signal CLK by performing a counting operation.

Then, at timing t34, the voltage of the reference signal RAMP is lower than the voltage (reset voltage Vreset) of the signal SIG (FIGS. 31(F) and 31(G)). As a result, the comparator circuit 24 of the AD converter ADC changes the voltage of the signal CP from a high level to a low level (FIG. 31(H)). The counter 25 of the AD converter ADC stops the counting operation based on this transition of the signal CP. The count value (count value CNTP) of the counter 25 at that time is a value corresponding to the reset voltage Vreset. The latch 26 holds this count value CNTP. Then, the counter 25 resets the count value.

Next, at timing t35, the imaging controller 18 stops generating the clock signal CLK with the end of the P-phase period TP. The reference signal generator 13 stops changing the voltage of the reference signal RAMP at this timing t35 (FIG. 31(F)). Then, in the period after timing t35, the reader 20 supplies the count value CNTP held in the latch 26 to the signal processor 15 as the image signal Spic0.

Next, at timing t36, the imaging controller 18 sets the voltage of the reference signal RAMP to the voltage V1 (FIG. 31(F)). As a result, since the voltage of the reference signal RAMP goes higher than the voltage (reset voltage Vreset) of the signal SIG, the comparator circuit 24 changes the voltage of the signal CP from a low level to a high level (FIG. 31(H)).

Next, at timing t37, the driver 12 changes the voltage of the control signal STRGL from a low level to a high level (FIG. 31(C)). As a result, in the five light-receiving pixels PGr arranged on the left side in the pixel pair 90, the transistor TRG is turned on, and the charges generated in the photodiode PD are transferred to the node FD (charge transfer operation). Then, the pixel block 100Gr outputs a voltage corresponding to the voltage of the node FD at that time. In this way the voltage of the signal SIG is the pixel voltage Vpix1 (FIG. 31(G)).

Then, at a timing when a predetermined time has elapsed from this timing t37, the driver 12 changes the voltage of the control signal STRGL from a high level to a low level (FIG. 31(C)). As a result, in the five light-receiving pixels PGr arranged on the left side of the pixel pair 90, the transistor TRG is turned off, and the charge transfer operation ends.

Then, during the period from timing t38 to timing t40 (D-phase period TD1), the AD converter ADC performs AD conversion based on the signal SIG. Specifically first, at timing t18, the reference signal generator 13 starts reducing the voltage of the reference signal RAMP from the voltage V1 by a predetermined degree of change (FIG. 31(F)). At timing t38, the imaging controller 18 starts generating the clock signal CLK. The counter 25 of the AD converter ADC counts the pulses of the clock signal CLK by performing a counting operation.

Then, at timing t39, the voltage of the reference signal RAMP is lower than the voltage (pixel voltage Vpix1) of the signal SIG (FIGS. 31(F) and 31(G)). As a result, the comparator circuit 24 of the AD converter ADC changes the voltage of the signal CP from a high level to a low level (FIG. 31(H)). The counter 25 of the AD converter ADC stops the counting operation based on this transition of the signal CP. The count value (count value CNTD1) of the counter 25 at that time is a value corresponding to the pixel voltage Vpix1. The latch 26 holds this count value CNTD1. Then, the counter 25 resets the count value.

Next, at timing t40, the imaging controller 18 stops generating the clock signal CLK with the end of the D-phase period TD1. The reference signal generator 13 stops changing the voltage of the reference signal RAMP at this timing t20 (FIG. 31(F)). Then, in the period after this timing t20, the reader 20 supplies the count value CNTD1 held in the latch 26 to the signal processor 15 as the image signal Spic0.

Next, at timing t41, the imaging controller 18 sets the voltage of the reference signal RAMP to the voltage V1 (FIG. 31(F)). As a result, since the voltage of the reference signal RAMP goes higher than the voltage (pixel voltage Vpix1) of the signal SIG, the comparator circuit 24 changes the voltage of the signal CP from a low level to a high level (FIG. 31(H)).

Next, at timing t42, the driver 12 changes the voltage of the control signal STRGL from a low level to a high level (FIGS. 31(C) and 31(D)). As a result, in the five light-receiving pixels PGr in the pixel block 100Gr, the transistor TRG is turned on, and the charges generated in the photodiode PD are transferred to the node FD (charge transfer operation). As a result, in the five light-receiving pixels PGr arranged on the left side in the pixel pair 90, the transistor TRG is turned on, and the charges generated in the photodiode PD are transferred to the node FD (charge transfer operation).

Next, at timing t43, the driver 12 changes the voltage of the control signal STRGR from a low level to a high level (FIGS. 31(C) and 31(D)). As a result, in the five light-receiving pixels PGr in the pixel block 100Gr, the transistor TRG is turned on, and the charges generated in the photodiode PD are transferred to the node FD (charge transfer operation). As a result, in the five light-receiving pixels PGr arranged on the right side in the pixel pair 90, the transistor TRG is turned on, and the charges generated in the photodiode PD are transferred to the node FD (charge transfer operation).

In this way, the transfer time is divided between the five light-receiving pixels PGr arranged on the left and the five light-receiving pixels PGr arranged on the right. As a result, boosts corresponding to five stray capacitances among the stray capacitances Ctr1 to Ctr10 (see FIG. 5) are applied to the node FD separately at timings t42 and t43. Therefore, it is possible to prevent too much boost from being applied to the node FD. Although the charge transfer is performed by dividing the ten light-receiving pixels PGr into two groups, the present invention is not limited to this, and the charge transfer may be performed by dividing the ten light-receiving pixels PGr into three or more groups.

Then, the pixel block 100Gr outputs a voltage corresponding to the voltage of the node FD at that time. In this way, the voltage of the signal SIG is the pixel voltage Vpix2 (FIG. 31(G)).

Then, at a timing when a predetermined time has elapsed from this timing t43, the driver 12 changes the voltages of the control signals STRGL and STRGR from a high level to a low level, respectively (FIGS. 31(C) and 31(D)). As a result, in the ten light-receiving pixels PGr, the transistor TRG is turned off, and the charge transfer operation ends.

Then, during the period from timing t44 to timing t45 (D-phase period TD2), the AD converter ADC performs AD conversion based on the signal SIG. Specifically, first, at timing t43, the reference signal generator 13 starts reducing the voltage of the reference signal RAMP from the voltage V1 by a predetermined degree of change (FIG. 31(F)). Furthermore, at this timing t43, the imaging controller 18 starts generating the clock signal CLK. The counter 25 of the AD converter ADC counts the pulses of the clock signal CLK by performing a counting operation.

Then, at timing t44, the voltage of the reference signal RAMP is lower than the voltage (pixel voltage Vpix2) of the signal SIG (FIGS. 31(F) and 31(G)). As a result, the comparator circuit 24 of the AD converter ADC changes the voltage of the signal CP from a high level to a low level (FIG. 31(H)). The counter 25 of the AD converter ADC stops the counting operation based on this transition of the signal CP. The count value (count value CNTD2) of the counter 25 at that time is a value corresponding to the pixel voltage Vpix2. The latch 26 holds this count value CNTD2. Then, the counter 25 resets the count value.

Next, at timing t45, the imaging controller 18 stops generating the clock signal CLK with the end of the D-phase period TD2. The reference signal generator 13 stops changing the voltage of the reference signal RAMP at this timing t45 (FIG. 31(F)). Then, in the period after timing t45, the reader 20 supplies the count value CNTD2 held in the latch 26 to the signal processor 15 as the image signal Spic0.

Next, at timing t46, the driver 12 changes the voltage of the control signal SSEL from a high level to a low level (FIG. 31(A)). As a result, in the pixel block 100Gr, the transistor SEL is turned off, and the pixel block 100Gr is electrically disconnected from the signal line VSL.

In this way, the reader 20 supplies the image signal Spic0 including the count values CNTP, CNTD1, and CNTD2 to the signal processor 15. For example, the signal processor 15 generates the pixel value VGr1 shown in FIG. 30(A) and the pixel value VGr2 shown in FIG. 30(B) based on the count values CNTP, CNTD1, and CNTD2 included in the image signal Spic0 using the principle of correlated double sampling. Specifically the signal processor 15 generates the pixel value VGr1 by subtracting the count value CNTP from the count value CNTD1, for example. Since the count value CNTD1 is a value corresponding to the sum of the amounts of light received by the five light-receiving pixels PGr arranged on the left side in the five pixel pairs 90 of the pixel block 100Gr, the signal processor 15 the pixel value VGr1 shown in FIG. 30(A) based on this count value CNTD1. Similarly the signal processor 15 generates the pixel value VGr2 by subtracting the count value CNTP from the count value CNTD2, for example. Since the count value CNTD2 is a value corresponding to the sum of the amounts of light received by the ten light-receiving pixels PGr of the pixel block 100Gr, the signal processor 15 can generate the pixel value VGr2 shown in FIG. 30(B) based on the count value CNTD2.

Although the pixel block 100Gr has been described above, the same applies to the pixel blocks 100R, 100Gb, and 100B. In this way the signal processor 15 generates image data DT1 including the pixel values VR1, VGr1, VGb1, and VB1, and image data DT2 including the pixel values VR2, VGr2, VGb2, and VB2, as shown in FIG. 30.

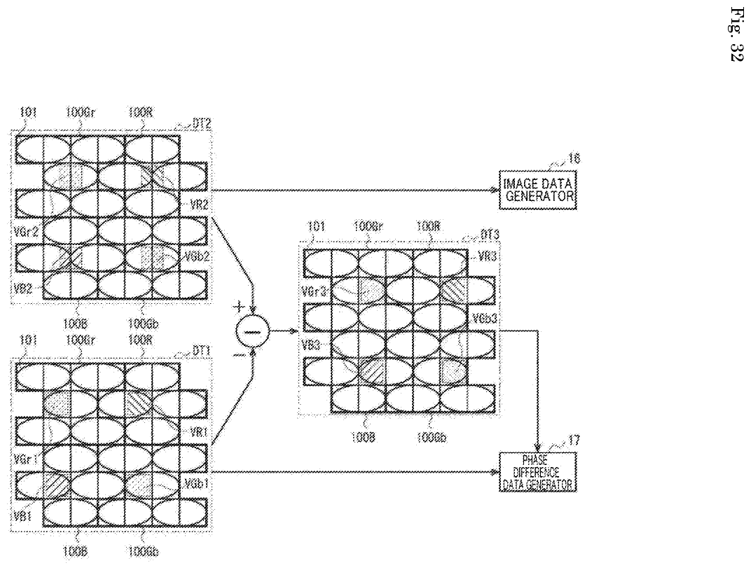

FIG. 32 is a diagram illustrating an example of image processing by the signal processor 15 in the imaging mode MA. First, the signal processor 15 generates image data DT3 by performing subtraction processing based on the image data DT1 and DT2.

Specifically, the signal processor 15 calculates the pixel value VGr3 by subtracting the pixel value VGr1 in the image data DT1 from the pixel value VGr2 in the image data DT2. This pixel value VGr3 is a value corresponding to the sum of the amounts of light received by the five light-receiving pixels PGr arranged on the right side in the five pixel pairs 90 of the pixel block 100Gr. That is, the pixel value VGr1 is a value corresponding to the sum of the amounts of light received by the five light-receiving pixels PGr arranged on the left side in the five pixel pairs 90 of the pixel block 100Gr, and the pixel value VGr2 is a value corresponding to the sum of the amounts of light received by the ten light-receiving pixels PGr of the pixel block 100Gr. Therefore, by subtracting the pixel value VGr1 from the pixel value VGr2, a value corresponding to the sum of the amounts of light received by the five light-receiving pixels PGr arranged on the right side in the five pixel pairs 90 of the pixel block 100Gr is obtained. In this way, since the pixel value VGr3 is a value corresponding to the sum of the amounts of light received by the five light-receiving pixels PGr arranged on the right side in the five pixel pairs 90, the pixel value VGr3 is arranged at the center of gravity of these five light-receiving pixels PGr as shown in FIG. 32.

Similarly, the signal processor 15 calculates the pixel value VR3 by subtracting the pixel value VR1 in the image data DT1 from the pixel value VR2 in the image data DT2. This pixel value VR3 is a value corresponding to the sum of the amounts of light received by the four light-receiving pixels PR arranged on the right side in the four pixel pairs 90 of the pixel block 100R. The pixel value VR3 is arranged at the center of gravity of the four light-receiving pixels PR arranged on the right side in the four pixel pairs 90 of the pixel block 100R.

The signal processor 15 calculates the pixel value VB3 by subtracting the pixel value VB1 in the image data DT1 from the pixel value VB2 in the image data DT2. This pixel value VB3 is a value corresponding to the sum of the amounts of light received by the four light-receiving pixels PB arranged on the right side in the four pixel pairs 90 of the pixel block 100B. The pixel value VB3 is arranged at the center of gravity of the four light-receiving pixels PB arranged on the right side in the four pixel pairs 90 of the pixel block 100B.

The signal processor 15 calculates the pixel value VGb3 by subtracting the pixel value VGb1 in the image data DT1 from the pixel value VGb2 in the image data DT2. This pixel value VGb3 is a value corresponding to the sum of the amounts of light received by the five light-receiving pixels PGb arranged on the right side in the five pixel pairs 90 of the pixel block 100Gb. The pixel value VGb3 is arranged at the center of gravity of the five light-receiving pixels PGb arranged on the right side in the five pixel pairs 90 of the pixel block 100Gb.

Then, the image data generator 16 of the signal processor 15 generates image data DP (FIG. 29(A)) indicating the captured image by performing predetermined image processing based on the image data DT2.

The phase difference data generator 17 of the signal processor 15 generates phase difference data DF indicating the image plane phase difference by performing predetermined image processing based on the image data DT1 and DT3. That is, the image data DT1 has a pixel value V at the light-receiving pixel P arranged on the left side in the plurality of pixel pairs 90, and the image data DT3 has a pixel value V at the light-receiving pixel P arranged on the right side in the plurality of pixel pairs 90. Therefore, the phase difference data generator 17 can generate phase difference data DF based on the image data DT1 and DT3.

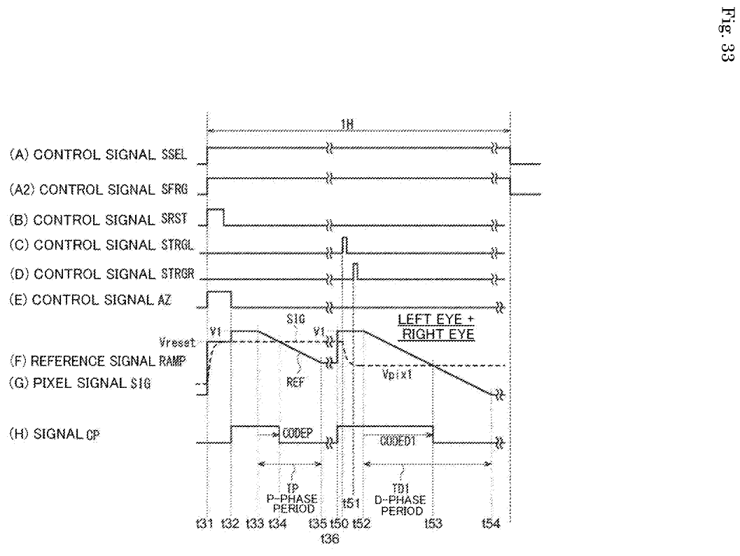

Here, an example of low-resolution readout in which ten pixels of the pixel block 100Gr are read out simultaneously will be described. FIG. 33 is a diagram illustrating an example of a readout operation in the case of low-resolution readout. (A) shows the waveform of the control signal SSEL, (A2) shows the waveform of the control signal SFDG, (B) shows the waveform of the control signal SRST, (C) shows the waveform of the control signal STRG (control signal STRGL) supplied to the light-receiving pixel PGr arranged on the left side in the pixel pair 90, (D) shows the waveform of the control signal STRG (control signal STRGR) supplied to the light-receiving pixel PGr arranged on the right side in the pixel pair 90, (E) shows the waveform of the control signal AZ, (F) shows the waveform of the reference signal RAMP, and (G) shows the waveform of the signal SIG, and (H) shows the waveform of the signal CP. In FIGS. 31(F) and 31(G), the waveforms of the reference signal RAMP and the signal SIG are shown using the same voltage axis. In addition, in this explanation, the waveform of the reference signal RAMP shown in FIG. 31(F) is the waveform of the voltage supplied to the input terminal of the comparator circuit 24 via the capacitive element 23, and the waveform of the signal SIG shown in FIG. 31(G) is the waveform of the voltage supplied to the input terminal of the comparator circuit 24 via the capacitive element 22.

First, from timing t31 to timing t35, the same processing as in FIG. 31 is performed. Next, at timing t36, the imaging controller 18 sets the voltage of the reference signal RAMP to the voltage V1 (FIG. 31(F)). As a result, since the voltage of the reference signal RAMP goes higher than the voltage (pixel voltage Vpix1) of the signal SIG, the comparator circuit 24 changes the voltage of the signal CP from a low level to a high level (FIG. 31(H)).

Next, at timing t50, the driver 12 changes the voltage of the control signal STRGL from a low level to a high level (FIGS. 31(C) and 31(D)). As a result, in the five light-receiving pixels PGr in the pixel block 100Gr, the transistor TRG is turned on, and the charges generated in the photodiode PD are transferred to the node FD (charge transfer operation). As a result, in the five light-receiving pixels PGr arranged on the left side in the pixel pair 90, the transistor TRG is turned on, and the charges generated in the photodiode PD are transferred to the node FD (charge transfer operation).

Next, at timing t51, the driver 12 changes the voltage of the control signal STRGR from a low level to a high level (FIGS. 31(C) and 31(D)). As a result, in the five light-receiving pixels PGr in the pixel block 100Gr, the transistor TRG is turned on, and the charges generated in the photodiode PD are transferred to the node FD (charge transfer operation). As a result, in the five light-receiving pixels PGr arranged on the right side in the pixel pair 90, the transistor TRG is turned on, and the charges generated in the photodiode PD are transferred to the node FD (charge transfer operation).

In this way, the transfer time is divided between the five light-receiving pixels PGr arranged on the left and the five light-receiving pixels PGr arranged on the right. As a result, boosts corresponding to five stray capacitances among the stray capacitances Ctr1 to Ctr10 (see FIG. 5) are applied to the node FD separately at timings t51 and t52. Therefore, it is possible to prevent too much boost from being applied to the node FD. Although the charge transfer is performed by dividing the ten light-receiving pixels PGr into two groups, the present invention is not limited to this, and the charge transfer may be performed by dividing the ten light-receiving pixels PGr into three or more groups.

Then, the pixel block 100Gr outputs a voltage corresponding to the voltage of the node FD at that time. In this way, the voltage of the signal SIG is the pixel voltage Vpix1 (FIG. 31(G)).

Then, at a timing when a predetermined time has elapsed from this timing t52, the driver 12 changes the voltages of the control signals STRGL and STRGR from a high level to a low level, respectively (FIGS. 31(C) and 31(D)). As a result, in the ten light-receiving pixels PGr, the transistor TRG is turned off, and the charge transfer operation ends.

Then, during the period from timing t52 to timing t53 (D-phase period TD1), the AD converter ADC performs AD conversion based on the signal SIG. Specifically, first, at timing t52, the reference signal generator 13 starts reducing the voltage of the reference signal RAMP from the voltage V1 by a predetermined degree of change (FIG. 31(F)). At this timing t52, the imaging controller 18 starts generating the clock signal CLK. The counter 25 of the AD converter ADC counts the pulses of the clock signal CLK by performing a counting operation.

Then, at timing t52, the voltage of the reference signal RAMP is lower than the voltage (pixel voltage Vpix1) of the signal SIG (FIGS. 31(F) and 31(G)). As a result, the comparator circuit 24 of the AD converter ADC changes the voltage of the signal CP from a high level to a low level (FIG. 31(H)). The counter 25 of the AD converter ADC stops the counting operation based on this transition of the signal CP. The count value (count value CNTD1) of the counter 25 at that time is a value corresponding to the pixel voltage Vpix1. The latch 26 holds this count value CNTD1. Then, the counter 25 resets the count value.

Next, at timing t54, the imaging controller 18 stops generating the clock signal CLK with the end of the D-phase period TD1. The reference signal generator 13 stops changing the voltage of the reference signal RAMP at this timing t54 (FIG. 31(F)). Then, in the period after timing t54, the reader 20 supplies the count value CNTD2 held in the latch 26 to the signal processor 15 as the image signal Spic0.

Next, the driver 12 changes the voltage of the control signal SSEL from a high level to a low level (FIG. 31(A)). As a result, in the pixel block 100Gr, the transistor SEL is turned off, and the pixel block 100Gr is electrically disconnected from the signal line VSL.

In this way, the reader 20 supplies the image signal Spic0 including the count values CNTP and CNTD1 to the signal processor 15. The signal processor 15 generates pixel values Vall for ten pixels of the pixel block 100Gr based on the count values CNTP and CNTD1 included in the image signal Spic0, for example, using the principle of correlated double sampling. Specifically, the signal processor 15 generates the pixel value Vall by subtracting the count value CNTP from the count value CNTD1, for example. Since the count value CNTD1 is a value corresponding to the sum of the amounts of light received by ten pixels of the pixel block 100Gr, the signal processor 15 can generate the pixel value Vall shown in FIG. 30(A) based on this count value CNTD1. Although the pixel block 100Gr has been described above, the same applies to the pixel blocks 100R, 100Gb, and 100B.

As explained above, according to the present embodiment, when transferring the stored charges of a plurality of pixels to the node FD, the charges are transferred separately at a plurality of timings (t37, t38) and (t51, t52). As a result, boosts corresponding to five stray capacitances among the stray capacitances Ctr1 to Ctr10 (see FIG. 5) are applied to the node FD separately at timings (t37, t38) and (t51, t52). Therefore, it is possible to prevent too much boost from being applied to the node FD.

Note that the present technology can have the following configuration.

(1)

An imaging device including:
a plurality of pixel blocks each having a plurality of light-receiving pixels including color filters of the same color, and the plurality of light-receiving pixels being divided into a plurality of pixel pairs each including two light-receiving pixels; and
a plurality of lenses each provided at a position corresponding to the plurality of pixel pairs, wherein
the pixel block includes:
a photoelectric converter,
a first floating diffusion having a plurality of combinations of transfer transistors having one set of ends connected to the photoelectric converter and being connected to the other set of ends of the plurality of transfer transistors;
a separation transistor having one end connected to the first floating diffusion;
a second floating diffusion connected to the other end of the separation transistor; and
a reset transistor having one end connected to the other end of the separation transistor, and the other end being supplied with a predetermined potential.
   (2)

The imaging device according to (1), wherein
the separation transistor is put into a disconnected state and the reset transistor is put into a connected state.
   (3)

The imaging device according to (1), wherein
at least one of the plurality of the transfer transistors is put into a connected state according to the connected state of the reset transistor.
   (4)

The imaging device according to (3), wherein
when the reset transistor is in a connected state, a potential of the first floating diffusion goes higher due to a first stray capacitance between a gate of the reset transistor and the first floating diffusion.
   (5)

The imaging device according to (1), wherein
after the separation transistor and the reset transistor are put into a connected state, the separation transistor is put into a disconnected state, and at least one of the transfer transistors is put into a connected state according to the disconnected state of the separation transistor.
   (6)

The imaging device according to (1), wherein
after the separation transistor and the reset transistor are put into a connected state, the separation transistor is put into a disconnected state, the reset transistor is put into a disconnected state, and at least one of the transfer transistors is put into a connected state according to reconnection of the reset transistor.
   (7)

The imaging device according to (1), wherein
after the separation transistor and the reset transistor are put into a connected state, the separation transistor is put into a disconnected state, and at least one of the transfer transistors is put into a connected state according to disconnection of the separation transistor.
   (8)

The imaging device according to (1), wherein
a second stray capacitance between the gate of the transfer transistor and the other end of the transfer transistor increases the potential of the first floating diffusion when the transfer transistor is put into a connected state.
   (9)

The imaging device according to (8), wherein
when transferring charges stored in the photoelectric converter connected to the one end of the transfer transistor to the first floating diffusion, the other transfer transistors to which charges have already been transferred are put into a connected state.
   (10)

The imaging device according to (8), wherein
the second stray capacitance corresponding to the other transfer transistor to which charges have already been transferred is configured to be larger than the second stray capacitance corresponding to the transfer transistor to which charges are to be transferred next.
   (11)

The imaging device according to (1), further including:
an amplification transistor having a gate connected to the first floating diffusion;
a selection transistor having one end connected to the amplification transistor and the other end connected to a signal line; and
a voltage control circuit that controls a voltage of the signal line when the transfer transistor is put into a connected state.
   (12)

The imaging device according to (8), wherein
when the plurality of transfer transistors are put into a connected state, the periods in which the plurality of transfer transistors are in a connected state do not overlap.
   (13)

The imaging device according to (1), wherein
when transferring charges stored in the photoelectric converter connected to the one end of the transfer transistor to the first floating diffusion, the other transfer transistor to which charges have already been transferred is put into a connected state.
   (14)

The imaging device according to (1), wherein
when transferring charges stored in the plurality of photoelectric converters to at least the first floating diffusion, periods of the connection state of the plurality of the transfer transistors do not overlap.
   (15)

The imaging device according to (1), further including:
an amplification transistor having a gate connected to the first floating diffusion;
a selection transistor having one end connected to the amplification transistor and the other end connected to a signal line; and
a voltage control circuit that controls a voltage of the signal line when the transfer transistor is put into a connected state.
   (16)
   The imaging device according to (1), wherein
the two light-receiving pixels are arranged in parallel in a first direction, and in each of the plurality of pixel blocks, the two pixel pairs arranged in a second direction intersecting the first direction are arranged to be shifted in the first direction.
   (17)

The imaging device according to (1), wherein
the plurality of pixel blocks include a first pixel block and a second pixel block,
in the first pixel block, the plurality of light-receiving pixels are arranged in a first arrangement pattern,
in the second pixel block, the plurality of light-receiving pixels are arranged in a second arrangement pattern.
   (18)

The imaging device according to (17), wherein
the number of the plurality of light-receiving pixels in the first pixel block is greater than the number of the plurality of light-receiving pixels in the second pixel block, and
the plurality of light-receiving pixels included in the first pixel block include the green color filter.

Aspects of the present disclosure are not limited to the aforementioned individual embodiments and include various modifications that those skilled in the art can achieve, and effects of the present disclosure are also not limited to the details described above. In other words, various additions, modifications, and partial deletion can be made without departing from the conceptual idea and the gist of the present disclosure that can be derived from the details defined in the claims and the equivalents thereof.

### REFERENCE SIGNS LIST

300 Voltage control circuit
1000 Imaging device
Crst Stray capacitance
Ctr11 to Ctr10 Stray capacitance
Cvsl Stray capacitance
FD1 First floating diffusion
FD2 Second floating diffusion
FDG Separation transistor
TRG1 to TRG10 Transfer transistor
PD Photodiode (photoelectric converter),
RST Reset transistor
SEL Select transistor
VSL Signal line

1. An imaging device comprising:
a plurality of pixel blocks each having a plurality of light-receiving pixels including color filters of the same color, and the plurality of light-receiving pixels being divided into a plurality of pixel pairs each including two light-receiving pixels; and
a plurality of lenses each provided at a position corresponding to the plurality of pixel pairs, wherein
the pixel block includes:
a photoelectric converter,
a first floating diffusion having a plurality of combinations of transfer transistors having one set of ends connected to the photoelectric converter and being connected to the other set of ends of the plurality of transfer transistors;
a separation transistor having one end connected to the first floating diffusion;
a second floating diffusion connected to the other end of the separation transistor; and
a reset transistor having one end connected to the other end of the separation transistor, and the other end being supplied with a predetermined potential.

2. The imaging device according to claim 1, wherein
the separation transistor is put into a disconnected state and the reset transistor is put into a connected state.

3. The imaging device according to claim 1, wherein
at least one of the plurality of the transfer transistors is put into a connected state according to the connected state of the reset transistor.

4. The imaging device according to claim 3, wherein
when the reset transistor is in a connected state, a potential of the first floating diffusion goes higher due to a first stray capacitance between a gate of the reset transistor and the first floating diffusion.

5. The imaging device according to claim 1, wherein
after the separation transistor and the reset transistor are put into a connected state, the separation transistor is put into a disconnected state, and at least one of the transfer transistors is put into a connected state according to the disconnected state of the separation transistor.

6. The imaging device according to claim 1, wherein
after the separation transistor and the reset transistor are put into a connected state, the separation transistor is put into a disconnected state, the reset transistor is put into a disconnected state, and at least one of the transfer transistors is put into a connected state according to reconnection of the reset transistor.

7. The imaging device according to claim 1, wherein
after the separation transistor and the reset transistor are put into a connected state, the separation transistor is put into a disconnected state, and at least one of the transfer transistors is put into a connected state according to disconnection of the separation transistor.

8. The imaging device according to claim 1, wherein
a second stray capacitance between the gate of the transfer transistor and the other end of the transfer transistor increases the potential of the first floating diffusion when the transfer transistor is put into a connected state.

9. The imaging device according to claim 8, wherein
when transferring charges stored in the photoelectric converter connected to the one end of the transfer transistor to the first floating diffusion, the other transfer transistors to which charges have already been transferred are put into a connected state.

10. The imaging device according to claim 9, wherein
the second stray capacitance corresponding to the other transfer transistor to which charges have already been transferred is configured to be larger than the second stray capacitance corresponding to the transfer transistor to which charges are to be transferred next.

11. The imaging device according to claim 1, further comprising:
an amplification transistor having a gate connected to the first floating diffusion;
a selection transistor having one end connected to the amplification transistor and the other end connected to a signal line; and
a voltage control circuit that controls a voltage of the signal line when the transfer transistor is put into a connected state.

12. The imaging device according to claim 8, wherein
when the plurality of transfer transistors are put into a connected state, the periods in which the plurality of transfer transistors are in a connected state do not overlap.

13. The imaging device according to claim 1, wherein
when transferring charges stored in the photoelectric converter connected to the one end of the transfer transistor to the first floating diffusion, the other transfer transistor to which charges have already been transferred is put into a connected state.

14. The imaging device according to claim 1, wherein
when transferring charges stored in the plurality of photoelectric converters to at least the first floating diffusion, periods of the connection state of the plurality of the transfer transistors do not overlap.

15. The imaging device according to claim 1, further comprising:
an amplification transistor having a gate connected to the first floating diffusion;
a selection transistor having one end connected to the amplification transistor and the other end connected to a signal line; and
a voltage control circuit that controls a voltage of the signal line when the transfer transistor is put into a connected state.

16. The imaging device according to claim 1, wherein
the two light-receiving pixels are arranged in parallel in a first direction, and
in each of the plurality of pixel blocks, the two pixel pairs arranged in a second direction intersecting the first direction are arranged to be shifted in the first direction.

17. The imaging device according to claim 1, wherein
the plurality of pixel blocks include a first pixel block and a second pixel block,
in the first pixel block, the plurality of light-receiving pixels are arranged in a first arrangement pattern,
in the second pixel block, the plurality of light-receiving pixels are arranged in a second arrangement pattern.

18. The imaging device according to claim 17, wherein
the number of the plurality of light-receiving pixels in the first pixel block is greater than the number of the plurality of light-receiving pixels in the second pixel block, and
the plurality of light-receiving pixels included in the first pixel block include the green color filter.
